(19) United States
(12) Patent Application Publication
(10) Pub. No.: US 2014/0239156 A1
(43) Pub. Date: Aug. 28, 2014

(54) PHOTOELECTRIC CONVERSION ELEMENT AND SOLID-STATE IMAGE PICKUP DEVICE

(71) Applicant: FUJIFILM Corporation, Tokyo (JP)

(72) Inventors: Masayuki HAYASHI, Kanagawa (JP); Yoshiki MAEHARA, Kanagawa (JP); Tetsuro MITSUI, Kanagawa (JP)

(73) Assignee: FUJIFILM CORPORATION, Tokyo (JP)

(21) Appl. No.: 14/275,308

(22) Filed: May 12, 2014

Related U.S. Application Data
(62) Division of application No. 11/838,264, filed on Aug. 14, 2007.

(30) Foreign Application Priority Data
Aug. 14, 2006 (JP) 2006-221140
Jul. 11, 2007 (JP) 2007-182317

(51) Int. Cl. H01L 27/146

(52) U.S. Cl. CPC H01L 27/14605
USPC 250/208.1

(57) ABSTRACT

A photoelectric conversion element comprises a photoelectric conversion section that includes: a pair of electrodes; and a photoelectric conversion layer disposed between the pair of electrodes, wherein the photoelectric conversion section further comprises between one of the pair of electrodes and the photoelectric conversion layer a first charge-blocking layer that restrains injection of charges from the one of the electrodes into the photoelectric conversion layer when a voltage is applied to the pair of electrodes, and the first charge-blocking layer comprises a plurality of layers.

### BACKGROUND OF THE INVENTION

1. Field of the Invention

The present invention relates to a photoelectric conversion element, and more particularly to a photoelectric conversion element of the type which has a photoelectric conversion layer disposed between a pair of electrodes and undergoes application of a voltage to the pair of electrodes.

2. Description of the Related Art

In single-plate solid-state color image pickup devices, notably CCD and CMOS image sensors, three or four kinds of color filters are arranged in a mosaic pattern on a photoelectric conversion element array. By this arrangement, color signals corresponding to color filters are put out from individual photoelectric conversion elements, and these color signals are formed into color images through signal processing.

However, in the case of using color filters of primary colors, about two-thirds the incident light is absorbed by the color filters, so the single-plate solid-state color image pickup devices provided with such color filters arranged in mosaic patterns have a problem that they have low sensitivities because of inferior efficiencies in light utilization. In addition, color signals of only one color are obtained from each photoelectric conversion element. As a result thereof, the devices are inferior in resolution and have an additional problem that false colors in particular are conspicuous.

Therefore, research and development of image pickup devices having a structure that photoelectric conversion films are stacked in three layers on a semiconductor substrate where signal readout circuitry is formed (hereinafter referred to as image pickup devices of multilayer type, too) are in progress in order to overcome those problems (as disclosed, e.g., in JP-T-2002-502120 and JP-A-2002-83946). Such an image pickup device of multilayer type is provided with a photo acceptance unit structure that photoelectric conversion films generating signal charges in response to, e.g., blue light (B), green light (G) and red light (R), respectively, are stacked in increasing order of distance from the plane of incoming radiation, and besides, signal readout circuits capable of independently reading out signal charges photo-generated in the respective photoelectric conversion films are provided for each photo acceptance unit.

In the case of multilayer-type image pickup devices of such a structure, most of incident light undergoes photoelectric conversion and can be read out, so efficiency in utilization of visible light is close to 100%, and besides, color signals of three colors R, G and B are obtained in each photo acceptance unit, resulting in formation of favorable images with high sensitivity and high resolution (inconspicuous false colors). The term “photoelectric conversion layer” as used in this specification refers to the layer absorbing light of specified wavelengths incident thereon and generating electrons and holes responsive to the quantity of light absorbed.

While performance evaluation of organic thin-film solar cells currently in use is made without application of any external electric field because the purpose of their use is to take out electric power, an external electric field is generally applied to the photoelectric conversion elements used in sensors disclosed in JP-T-2002-502120 and JP-A-2002-83946 for the purpose of improving photoelectric conversion efficiency and response speed since it is necessary for the photoelectric conversion elements to unleash their photoelectric conversion efficiency.

When a voltage is applied between electrodes, hole injection or electron injection from the electrodes by external electric field takes place, and thereby an increase in dark current occurs. So it has been impossible to obtain elements with great photo current/dark current ratios. Under these circumstances, it can be said that the technique to suppress dark current as effectively as possible without reducing photo current is one of important techniques for photoelectric conversion elements.

There has so for been known a method of suppressing dark current by inserting between an electrode and a photoelectric conversion layer a blocking layer functioning as a Schottky barrier against carrier injection (dark current) from the electrode. In this method, a material which can make the Schottky barrier to the electrode as high as possible is used as the blocking layer for the purpose of suppressing carrier injection from the electrode under application of an external electric field (See, e.g., in JP-A-5-129576 and JP-T-2003-515933).

In fact, however, carrier injection from an electrode in quantity much greater than expected from the height of a Schottky barrier is caused by application of a voltage. One of causes of this phenomenon is thought to be attributable to carrier injection from an electrode via intermediate levels low in barrier, such as impurity levels and defect levels, present in a blocking layer.

FIGS. 18A and 18B is a schematic diagram illustrating the structure and problems of a traditional photoelectric conversion element having charge blocking layers, and FIG. 18A is a cross-sectional diagram of the photoelectric conversion element and FIG. 18B is an energy diagram illustrating the carrier injections via intermediate levels of the charge blocking layers under application of a voltage.

The photoelectric conversion element shown in FIG. 18A has a structure that a pixel electrode (transparent electrode) 710 is provided on a transparent substrate 700, and on the transparent electrode 710 a single-layer electron-blocking layer 720, a photoelectric conversion layer 730 and a single-layer hole-blocking layer 740 are stacked in the order of mention, and further an opposite electrode 750 is provided.

In the structure shown in FIG. 18A, reduction in dark current is supposed to occur adequately since hole and electron blocking layers are provided, but the fact is that dark-current reduction worth expecting cannot be achieved. This is because, as shown in FIG. 18B, electrons are injected from the electrode 710 into the photoelectric conversion layer 730 via intermediate levels (S30) emerging on the interface surface and inside of the electron blocking layer 720 (the state of injections are shown by an arrow in the figure), while holes are injected from the electrode 750 into the photoelectric conversion layer 730 via intermediate levels (S40) emerging on the interface surface or inside of the hole blocking layer 740 (the state of injections are shown by an arrow in the figure).

Therefore, it is required for enhancing the sensitivity of photoelectric conversion elements to work on the development of techniques for further suppressing dark current.

According to the technique disclosed in JP-A-5-129576, the organic photoelectric conversion element has a blocking layer predominantly composed of silicon oxide between an organic photoreceptive layer and an electrode. However, when a voltage is applied externally to such an element, dark current is increased in actuality by carrier injection from the electrode via impurity levels and defect levels preset in the blocking layer, and to this problem the technique disclosed in JP-A-5-129576 offers no solution.

In the organic thin-film solar cell system disclosed in JP-T-2003-515933, on the other hand, an exciton blocking layer is inserted between an electrode and an organic photoelectric conversion layer. The guideline for designing the exciton blocking layer consists in the use of a material having an energy gap (Eg) greater than the Eg of a material forming the adjacent photoelectric conversion layer in the exciton blocking layer. No matter what material is used, however, there occurs carrier injection from the electrode via impurity levels and defect levels present in the blocking layer. JP-T-2003-515933 is silent on this point and doesn't suggest any effective solution to the carrier injection coming from impurity levels of the blocking layer and so on.

As another cause of the occurrence of carrier injection from an electrode in quantity much greater than expected from the height of a Schottky barrier under application of a voltage, it is supposed that, when the blocking layer is formed into a single film, the single film formed is not uniform in microscopic areas, so there are sites at which the electrode and the photoelectric conversion layer beneath the blocking layer are in local proximity to each other. When microscopic proximity sites are present, charge injection via the microscopic proximity sites and the resulting increase in dark current are thought to occur on grounds that a strong electric field is imposed on those sites and the film quality deteriorates at those sites to result in failure to develop the injection blocking ability to a sufficient degree.

Increasing the thickness of a blocking layer is effective for suppression of such a dark current. However, a simple increase in the thickness of a single blocking layer, though can bring about reduction in dark current, causes an increase in internal resistance also. As a result, the quantity of readable signal charges is reduced and, in some cases, there may occur a drop in sensitivity. By contrast, in the case of using a material of the kind which gushes carriers responsible for generating a dark current from imperfections in the layer, an increase in dark current is brought about by increasing the layer thickness. It is therefore important to select a material which can ensure an even profile for the blocking layer formed, and what's more, it is required to simultaneously achieve an energy barrier formation for prevention of the injection, formation of an energy barrier-free interface allowing smooth reading of signals from a photoelectric conversion layer and creation of a state in which the inside resistance is low and no carrier springs out. However, it is difficult for a single-layer film made of only one material to satisfy the foregoing requirements.

The Patent Documents above are silent about effective measures against the aforesaid points.

### SUMMARY OF THE INVENTION

The invention has been made on the basis of the considerations as mentioned above, and an object thereof is to provide a photoelectric conversion element which makes it possible to suppress the injection of charges (electrons and holes) from intermediate level electrodes into a photoelectric conversion layer and thereby permits effective reduction in dark current.

The photoelectric conversion element according to one aspect of the invention is a photoelectric conversion element comprising a photoelectric conversion section that includes: a pair of electrodes; and a photoelectric conversion layer disposed between the pair of electrodes, wherein the photoelectric conversion section further comprises between one of the pair of electrodes and the photoelectric conversion layer a first charge-blocking layer that restrains injection of charges from the one of the electrodes into the photoelectric conversion layer when a voltage is applied to the pair of electrodes, and the first charge-blocking layer comprises a plurality of layers.

In the present photoelectric conversion element, at least two of the plurality of layers included in the first charge-blocking layer may be different from each other in materials with which they are made.

In the present photoelectric conversion element, the first blocking layer may have a thickness of 10 nm to 200 nm.

In the present photoelectric conversion element, the first charge-blocking layer may have at least one inorganic material layer including an inorganic material.

In the present photoelectric conversion element, the first charge-blocking layer may further comprise at least one organic material layer including an organic material.

In the present photoelectric conversion element, the first charge-blocking layer may comprise an inorganic material layer including an inorganic material and an organic material layer including an organic material, in order of mention when viewed from a side of the one of the electrodes.

In the present photoelectric conversion element, the photoelectric conversion section may further comprise between the other one of the pair of electrodes and the photoelectric conversion layer a second charge-blocking layer that restrains injection of charges from the other one of the electrodes into the photoelectric conversion layer when a voltage is applied to the pair of electrodes, and the second charge-blocking layer comprises a plurality of layers.

In the present photoelectric conversion element, at least two of the plurality of layers included in the second charge-blocking layer may be different from each other in materials with which they are made.

In the present photoelectric conversion element, the second blocking layer may have a thickness of 10 nm to 200 nm.

In the present photoelectric conversion element, the second charge-blocking layer may have an inorganic material layer including at least one inorganic material.

In the present photoelectric conversion element, the second charge-blocking layer may further comprise an organic material layer including an organic material.

In the present photoelectric conversion element, the second charge-blocking layer may comprise an inorganic material layer including an inorganic material and an organic material layer including an organic material, in order of mention when viewed from a side of the other one of the electrodes.

In the present photoelectric conversion element, the inorganic material may contain Si, Mo, Ce, Li, Hf, Ta, Al, Ti, Zn, W or Zr.

In the present photoelectric conversion element, the inorganic material may contain an oxide.

In the present photoelectric conversion element, the oxide may contain SiO.

In the photoelectric conversion element, each of the one pair of electrodes may contain a transparent conductive oxide (TCO).

In the present photoelectric conversion element, a value obtained by dividing a voltage externally applied to the pair of electrodes by an electrode-to-electrode distance of the pair of electrodes is from 1.0×10⁵ V/cm to 1.0×10⁷ V/cm.

The present photoelectric conversion element may further comprises: a semiconductor substrate above which the photoelectric conversion section is disposed in at least one layer; a charge storage section, formed in the semiconductor substrate, that stores charges generated in the photoelectric conversion layer of the photoelectric conversion section; and a connecting section that connects electrically an electrode for extracting the charges, which is one of the pair of electrodes in the photoelectric conversion section, to the charge storage section.

The present photoelectric conversion element may further comprise, in the semiconductor substrate, an in-substrate photoelectric conversion portion that absorbs light transmitted by the photoelectric conversion layer of the photoelectric conversion section, generates charges responsive to the transmitted light and stores the charges.

In the present photoelectric conversion element, the in-substrate photoelectric conversion portion may comprise a plurality of photodiodes which are stacked in the semiconductor substrate and absorb light of different colors, respectively.

In the present photoelectric conversion element, the in-substrate photoelectric conversion portion may comprise a plurality of photodiodes juxtaposed in a direction perpendicular to an incidence direction of incident light inside the semiconductor substrate, the photodiodes absorbing light of different colors respectively.

In the present photoelectric conversion element, the photoelectric conversion section may be disposed in one layer above the semiconductor substrate, the plurality of photodiodes may be a photodiode for blue color, which has a pn junction face formed at a position allowing absorption of blue light, and a photodiode for red color, which has a pn junction face formed at a position allowing absorption of red light, and the photoelectric conversion layer of the photoelectric conversion section may be a layer capable of absorbing green light.

The solid-state image pickup device according to another aspect of the invention is a solid-state image pickup device comprising: a plurality of photoelectric conversion elements in array arrangement, each of the photoelectric conversion elements being the photoelectric conversion elements as described above; and a signal readout section that reads out signals responsive to the charges stored in each of the charge storage sections of said plurality of photoelectric conversion elements.

### BRIEF DESCRIPTION OF DRAWINGS

FIG. 1 is a schematic cross-sectional diagram showing an example of the makeup of a photoelectric conversion element having a charge blocking layer according to an embodiment of the invention;

FIGS. 2A and 2B is an energy diagrams each illustrating a state of intermediate levels in the charge blocking layer of double-layer structure as shown in FIG. 1;

FIGS. 3A to 3D are illustrations demonstrating combinations of materials which are used for constituent layers, respectively, when the charge blocking layer as shown in FIG. 1 has a triple-layer structure;

FIG. 4 is a schematic cross-sectional diagram showing a photoelectric conversion element having an electron blocking layer of triple-layer structure and a hole blocking layer of triple-layer structure;

FIG. 5 is an energy diagram illustrating a state of carrier movements via intermediate levels of charge blocking layers under application of a voltage to the photoelectric conversion element shown in FIG. 4;

FIG. 6 is a schematic cross-sectional diagram showing the outline of a makeup of a photoelectric conversion element according to an embodiment of the invention;

FIG. 7 is a schematic cross-sectional diagram showing a variation of the photoelectric conversion element shown in FIG. 6;

FIG. 8 is a schematic cross-sectional diagram showing the outline of a makeup of another photoelectric conversion element according to an embodiment of the invention;

FIG. 9 is a schematic cross-sectional diagram showing a variation of the photoelectric conversion element shown in FIG. 8;

FIG. 10 is a schematic cross-sectional diagram showing the outline of a makeup of still another photoelectric conversion element according to an embodiment of the invention;

FIG. 11 is a schematic cross-sectional diagram showing a variation of the photoelectric conversion element shown in FIG. 10;

FIG. 12 is a schematic cross-sectional diagram of a pixel of solid-state image pickup device for illustration of the third embodiment of the invention;

FIG. 13 is a schematic cross-sectional diagram of the intermediate layer shown in FIG. 12;

FIG. 14 is a schematic cross-sectional diagram of a pixel of solid-state image pickup device for illustration of the fourth embodiment of the invention;

FIG. 15 is a schematic cross-sectional diagram of a pixel of solid-state image pickup device for illustration of the fifth embodiment of the invention;

FIG. 16 is a schematic cross-sectional diagram of a solid-state image pickup device for illustration of the sixth embodiment of the invention;

FIG. 17 is a table showing results obtained in Examples and Comparative Examples; and

FIGS. 18A and 18B are schematic diagrams illustrating the structure and problems of a traditional photoelectric conversion element having charge blocking layers.

### DETAILED DESCRIPTION OF THE INVENTION

Modes for carrying out the invention are illustrated below by reference to drawings.

In a photoelectric conversion element including a pair of electrodes and a photoelectric conversion layer disposed between the pair of electrodes, the present applicant has found that, when a first charge-blocking layer to restrain the injection of charges from one of the pair of electrodes into the photoelectric conversion layer is provided between the one of a pair of electrodes and the photoelectric conversion layer, dark current can be suppressed more effectively by designing the first charge-blocking layer to have a multilayer structure as compared with the case where a first charge-blocking layer has a single-layer structure. In addition, it has been found that, in another makeup also where a second charge-blocking layer to restrain the injection of charges from the other of the pair of electrodes into the photoelectric conversion layer is further provided between the other of the pair of electrodes and the photoelectric conversion layer, dark current can be suppressed more strongly by designing the second charge-blocking layer to have a multilayer structure as compared with the case where a second charge-blocking layer has a single-layer structure. Furthermore, it has been found that, when at least two layers of the plurality of layers constituting each of the first charge-blocking layer and the second charge-blocking layer are different from each other in materials with which they are made, further enhancement of dark current suppression effect can be achieved. Moreover, it has been found that, when at least two of the plurality of layers are a layer including an inorganic material and a layer including an organic material, respectively, effectiveness of charge blocking layers in suppressing dark currents can be further improved. Concrete structures of charge blocking layers in the following embodiments of the invention are illustrated below.

### First Embodiment

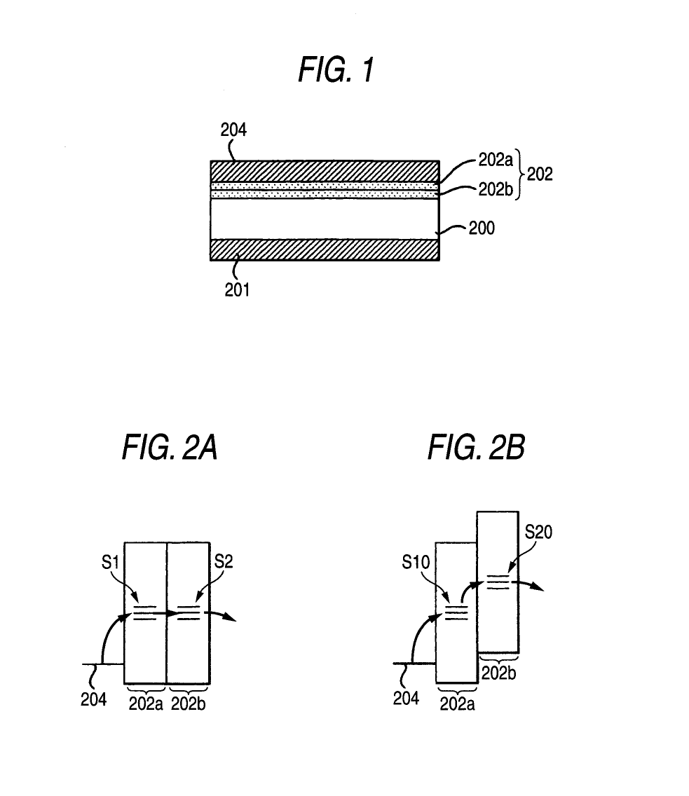

FIG. 1 is a schematic cross-sectional diagram showing an example of the structure of a photoelectric conversion element having a charge blocking layer according to an embodiment of the invention.

In FIG. 1, the reference numeral 200 represents a photoelectric conversion layer, the reference numeral 202 a charge blocking layer having a double-layer structure, the reference symbols 202a and 202b layers constituting the charge blocking layer 202, and the reference numerals 201 and 204 electrodes.

When the electrode 204 is arranged as, say, an electrode on the side of light incidence, it is necessary for the electrode 204 to transmit the incident light to the photoelectric conversion layer 200, so the electrode 204 is preferably made up of highly transparent materials. Examples of a highly transparent electrode include transparent conductive oxides (TCO). In addition, as seen in a configuration of the image pickup device illustrated hereinafter, there is a case where transmission of incident light to a region beneath the electrode 201 is also required, so it is also preferable that the electrode 201 is made up of highly transparent materials. On the other hand, even when the electrode 201 is arranged as an electrode on the side of light incidence, it is preferable that both the electrode 204 and the electrode 201 are made up of highly transparent materials.

The charge blocking layer 202 is a layer for restraining transfer of charges from the electrode 204 to the photoelectric conversion layer 200 when a voltage is applied between the electrodes 201 and 204. In the case where the charge blocking layer 202 has a single-layer structure, intermediate levels (impurity levels and so on) are present in a material constituting the charge blocking layer 202 in itself, and transfer of charges (electrons and holes) via these intermediate levels occurs to result in an increase of dark current. So the charge blocking layer in the present embodiment is designed to have a double-layer structure, not a single-layer structure, with the intention of avoiding such transfer from occurring.

It is thought that, when an interface is formed between the layer 202a and the layer 202b constituting the charge blocking layer 202, dark current can be suppressed because discontinuity occurs in intermediate levels present in each of the layers 202a and 202b to result in difficulty of transferring carriers via intermediate levels and the like. However, when the layers 202a and 202b are formed from the same material, the case can occur wherein the intermediate levels in the layer 202a and those in the layer 202b become totally the same, so it is favorable for further enhancement of dark current suppression effect that the layer 202a and the layer 202b are formed from materials different from each other.

In FIGS. 2A and 2B, energy diagrams each illustrating the state of intermediate levels in the charge blocking layer of double-layer structure as shown in FIG. 1 are indicated. Therein, FIG. 2A shows a case where the layers 202a and 202b are made from the same material, and FIG. 2B shows a case where the layers 202a and 202b are made from different materials, respectively.

When the layers 202a and 202b are made from the same material, as mentioned above, an interface is formed. So it is possible to suppress dark current as compared with the case where the charge blocking layer has a single-layer structure. However, in a case where intermediate levels in the layer 202a and those in the layer 202b (S1, S2) are present at energy positions of almost the same order as shown in FIG. 2A, there occurs charge transfer via the intermediate levels in each of the layers 202a and 202b (as shown by arrows in the figure).

When the layers 202a and 202b are therefore made from different materials, respectively, it becomes feasible to make the intermediate levels in the layer 202b (S20) lie in positions, e.g., higher than those in the layer 202a (S10) as shown in FIG. 2B. So these energy level differentials pose a barrier, and charge transfer is reduced so much more for that. Thus, positions of intermediate levels in these constituent layers can be positively spread out by forming two layers constituting the charge blocking layer 202 with different materials respectively; as a result, effects of inhibiting carrier transfer via intermediate levels can be enhanced.

In FIG. 1 showing a case where the photoelectric conversion element has one charge blocking layer, even when a charge blocking layer for restraining the charge transfer from the electrode 201 to the photoelectric conversion layer under application of a voltage between the electrodes 201 and 204 is provided between the electrode 201 and the photoelectric conversion layer 200, dark current can be suppressed by designing the charge blocking layer to have a double-layer structure, and further suppression of dark current can be achieved by forming these two layers with different materials respectively.

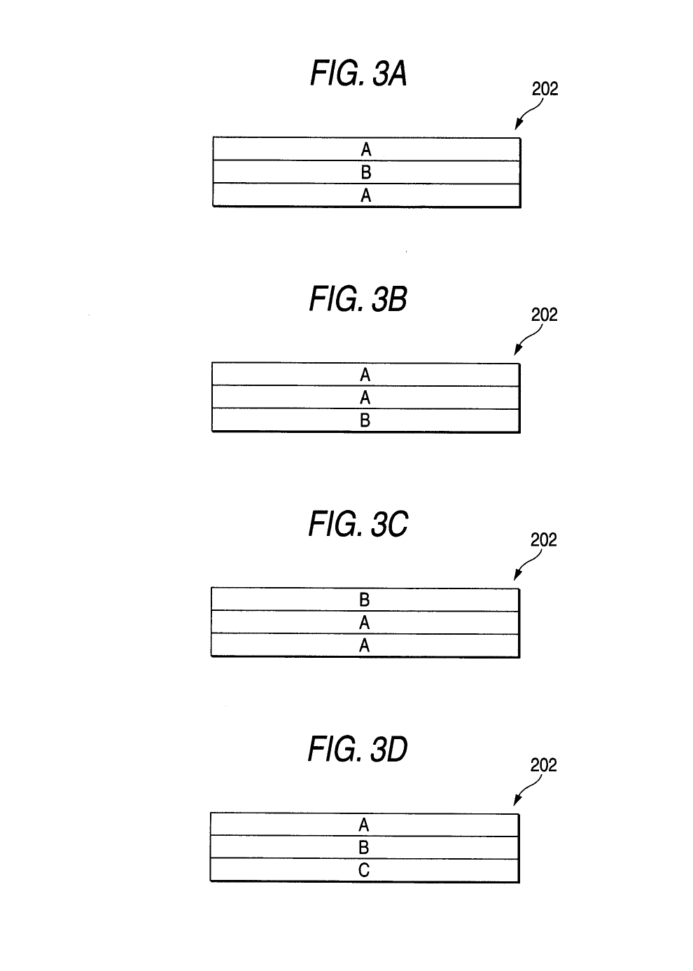

While the case where the charge blocking layer 202 has a double-layer structure is illustrated above, this layer may have a structure made up of three or more layers. Herein, as mentioned above, at least two intermediate-level groups different in level can be positively formed insides the charge blocking layer as far as at least two of the layers constituting the charge blocking layer are different in materials with which they are made. In the case of forming the charge blocking layer into, e.g., a triple-layer structure, as shown in FIG. 3A, it is adequate for the purpose that the lowest layer and the uppermost layer are made from a material A and the intermediate layer is made from a material B different from the material A. In another way, as shown in FIG. 3B, the lowest layer may be made from the material B, while the intermediate and uppermost layers may be made from the material A. In still another way, as shown in FIG. 3C, the lowest and intermediate layers may be made from the material A, while the uppermost layer may be made form the material B. Alternatively, as shown in FIG. 3D, the lowest layer may be made from a material C different from both materials A and B, and the intermediate and uppermost layers may be made from the materials B and A, respectively.

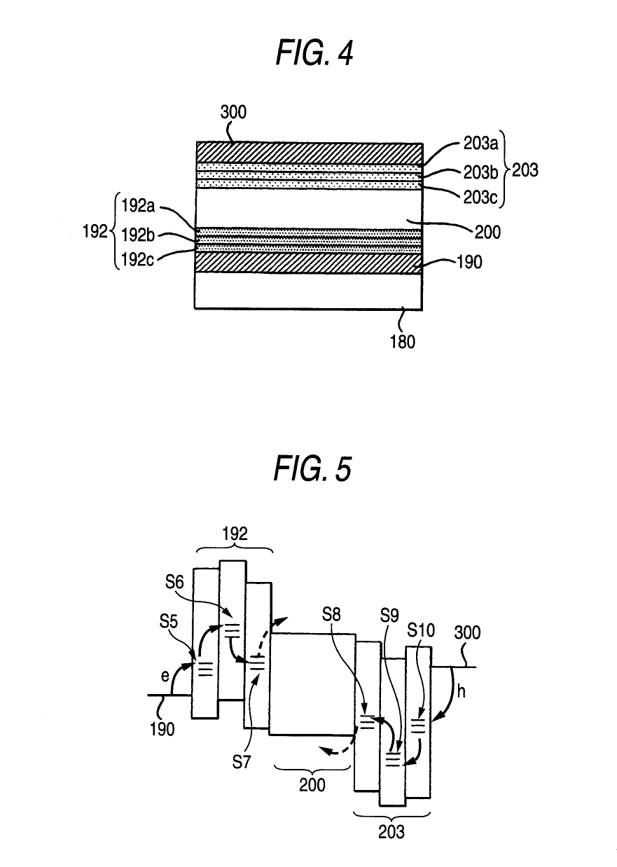

FIG. 4 is a schematic cross-sectional diagram showing another example of the photoelectric conversion element according to the present embodiment (the photoelectric conversion element having an electron blocking layer of triple-layer structure and a hole blocking layer of triple-layer structure). FIG. 5 is an energy diagram for illustrating the state of charge transfers via intermediate levels in the electron blocking layer and those in the hole blocking layer under application of a voltage to the photoelectric conversion element shown in FIG. 4.

More specifically, the photoelectric conversion element shown in FIG. 4 has a structure that a pixel electrode (a transparent electrode) 190 is provided on a transparent substrate 180, and on the transparent electrode 190 an electron blocking layer of triple-layer structure 192 (which has a structure that layers 192a to 192c are stacked on top of each other), a photoelectric conversion layer 200 and a hole blocking layer 203 (which has a structure that layers 203a to 203c are stacked on top of each other) are stacked in the order of mention, and on this stacked matter an opposite electrode 300 is further provided. At least two of the layers 192a to 192c are required to be made from different materials, respectively. Herein, a situation is chosen in which materials of the layers 192a to 192c are different from one another. Likewise, it is required for at least two of the layers 203a to 203c to be made from different materials respectively. Herein also, a situation is chosen in which materials of the layers 203a to 203c are different from one another.

By having such a structure, as shown in FIG. 5, the intermediate-level groups of constituent layers (S5, S6 and S7) in the electron blocking layer 192 becomes different in energy level from one another at the time of voltage application, and these energy-level differentials pose energy barriers, so electrons come to resist being transferred. Likewise, the intermediate-level groups of constituent layers (S8, S9 and S10) in the hole blocking layer 203 are different in energy level from one another, and these energy-level differentials pose energy barriers, so holes come to resist being transferred.

Then, effects produced by forming each blocking layer with a plurality of layers stacked on top of each other are described below, except for details on intermediate levels.

According to the aforementioned technique of shifting intermediate levels present in each layer by giving thereto a multilayer structure, dark currents are suppressed by “inhibiting transport of injected charges”. On the other hand, the formation of each blocking layer with a plurality of layers has an additional effect of reducing a dark current through “suppression of charge injection from an electrode”.

In suppressing the charge injection from an electrode, “to heighten an energy barrier between the electrode and a layer adjacent thereto” and “to make the blocking layer uniform in quality and keep the electrode from being brought into close proximity with the layer beneath the blocking layer (a photoelectric conversion layer)” are important.

The former is an approach of setting up an energy barrier against injection, and the latter is an approach of preventing the formation of leak sites from the viewpoint of a physical structure by proximity of the electrode to a photoelectric conversion layer resulting from intrusion of an electrode material into blocking layer's microscopic imperfections.

When a structure formed of a plurality of layers is given to a blocking layer, it becomes possible to design the layer adjoining an electrode among the plurality of layers to have an energy barrier differentiated from that of the electrode and design the other layers not adjoining the electrode to have uniformity as well as charge transportability and thereby prevent the appearance of leak sites. In other words, it is feasible to divide functions as appropriate and allocate the divided ones to various layers.

As a result of our intensive study made from the standpoint mentioned above, it has been found that a dark current can be suppressed more markedly, and besides no impairment in the reading of signal charges can be attained by using an inorganic material layer including an inorganic material as a blocking layer adjoining the electrode and an organic material layer including an organic material as its lower blocking layer (a blocking layer disposed between the inorganic material layer and a photoelectric conversion layer).

More specifically, it has been found that more noticeable suppression of dark currents and no impairment in the reading of signal charges can be attained when the layer 202a and the layer 202b in FIG. 1 were designed as an inorganic material layer and an organic material layer, respectively, or A and B in each of FIG. 3B and FIG. 3D are designed as an inorganic material layer and an organic material layer, respectively, or A and B in FIG. 3C are designed as an organic material layer and an inorganic material layer, respectively, or 192c and 203a in FIG. 4 are designed as inorganic material layers and 192a, 192b, 203b and 203c in FIG. 4 are designed as organic material layers.

As an inorganic material that constitutes the inorganic material layer, any of Si, Mo, Ce, Li, Hf, Ta, Al, Ti, Zn, W and Zr can be used to advantage. Alternatively, it is also advantageous to use an oxide as the inorganic material. As the oxide, the use of SiO in particular is preferred.

For prevention of charge injection from an electrode, the inorganic material layer is required to have such an ionization energy Ip as to generate an energy barrier between its work function and a work function of the electrode adjacent thereto, and it is preferable that the inorganic material layer has greater Ip. When a charge blocking layer is made up of such a simple inorganic material layer alone, however, the effect of preventing charge injection cannot be produced sufficiently so long as the layer has a small thickness, because leak sites appear between the electrode and a photoelectric conversion layer; while it becomes difficult to read out signal charges when the layer has a great thickness, because the great thickness causes reduction in charge transportability.

Therefore, it is important to further provide an organic material layer as a lower layer of the inorganic material layer. And it is preferable that the organic material layer is a layer having uniformity as well as charge transportability high enough to transport signal charges generated in the photoelectric conversion layer and made up of a material limited in number of carriers responsible for dark current produced from the material.

By having such a makeup, it becomes possible to render a blocking layer thick and uniform without attended by not only an increase in the dark current originating from the blocking layer but also a decrease in photoelectric conversion efficiency, and suppress the dark current owing to the effect produced by combining the organic material layer with the inorganic material layer.

Next, potential organic materials to make up each of the hole blocking layer and the electron blocking layer are described.

### (Hole Blocking Layer)

In a hole blocking layer, electron-accepting organic materials can be used.

Electron-accepting materials usable herein include oxadiazole derivatives such as 1,3-bis(4-tert-butylphenyl-1,3,4-oxadiazolyl)phenylene (OXD-7); anthraquinodimethane derivatives; diphenylquinone derivatives; bathocuproine and bathophenanthroline, and derivatives thereof; triazole compounds; tris(8-hydroxyquinolinato)aluminum complexes; bis(4-methyl-8-quinolinato)aluminum complexes; distyrylarylene derivatives; and silole compounds. In addition, it is possible to use other materials as far as they have sufficient electron transportability regardless of whether or not to be electron-accepting organic materials. For example, porphyrin compounds and styryl compounds such as DCM (4-dicyanomethylene-2-methyl-6-(4-(dimethylaminostyryl))-4H pyran and 4H-pyran based compounds can be used.

The thickness of a hole blocking layer is preferably from 10 nm to 200 nm, far preferably from 30 nm to 150 nm, particularly preferably from 50 nm to 100 nm. This is because, when this thickness is too thin, effect of suppressing dark current is lowered, while the photoelectric conversion efficiency is reduced when the thickness is too thick.

Examples of candidates for the hole blocking material include the materials represented by the following formulae. Herein, Ea stands for an electron affinity the corresponding material has, and Ip stands for an ionization potential the corresponding material has.

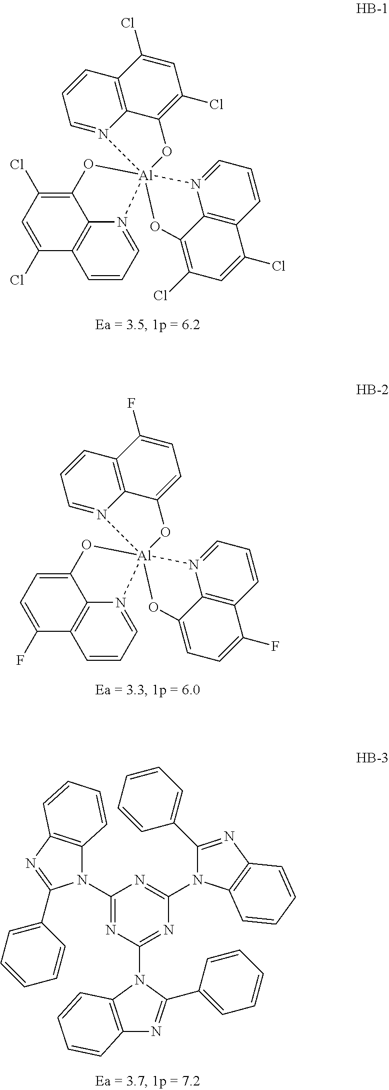

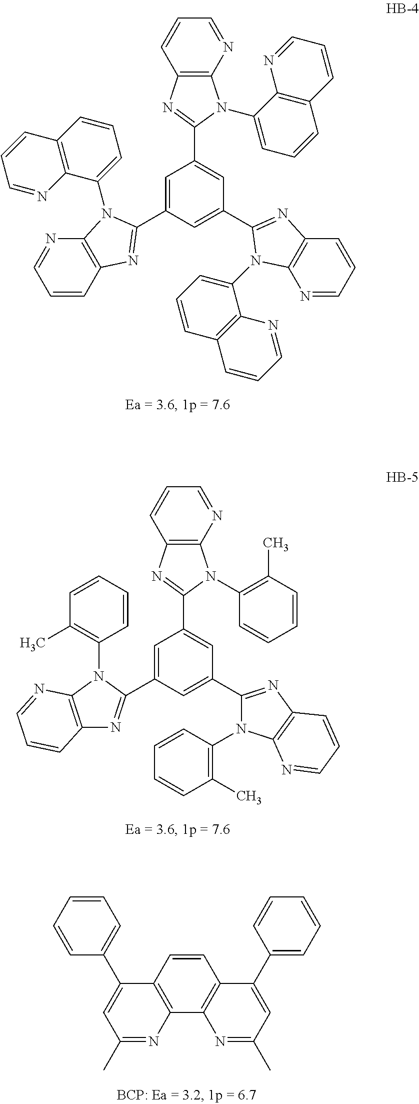 [SMILES: c1cnc2c(-n3c(-c4cc(-c5nc6cccnc6n5-c5cccc6cccnc56)cc(-c5nc6cccnc6n5-c5cccc6cccnc56)c4)nc4cccnc43)cccc2c1 ; Cc1ccccc1-n1c(-c2cc(-c3nc4cccnc4n3-c3ccccc3C)cc(-c3nc4cccnc4n3-c3ccccc3C)c2)nc2cccnc21 ; Cc1cc(-c2ccccc2)c2ccc3c(-c4ccccc4)cc(C)nc3c2n1]

As to materials practically usable in the hole blocking layer, the range of their choices is restricted by what materials are used for the adjacent electrode and the adjacent photoelectric conversion layer, respectively. Specifically, materials having an ionization potential (Ip) at least 1.3 eV greater than the work function of a material used for the adjacent electrode and an electron affinity (Ea) equivalent to or greater than the Ea of a material used for the adjacent photoelectric conversion layer are suitable as the materials used practically.

### (Electron Blocking Layer)

In the electron blocking layer, electron-donating organic materials can be used. Examples of a low molecular material of such a kind include aromatic diamine compounds such as N,N′-bis(3-methylphenyl)-(1,1′-biphenyl)-4,4′-diamine (TPD) and 4,4′-bis[N-(naphthyl)-N-phenyl-amino]biphenyl (α-NPD), oxazole, oxadiazole, triazole, imidazole, imidazolone, stilbene derivatives, pyrazoline derivatives, tetrahydroimidazole, polyarylalkanes, butadiene, 4,4′,4″-tris(N-(3-methylphenyl) N-phenylamino)triphenylamine (m-MTDATA), porphyrin compounds such as porphine, tetraphenylporphine copper, phthalocyanine, copper phthalocyanine and titanium phthalocyanine oxide, triazole derivatives, oxadiazole derivatives, imidazole derivatives, polyarylalkane derivatives, pyrazoline derivatives, pyrazolone derivatives, phenylenediamine derivatives, anilamine derivatives, amino-substituted chalcone derivatives, oxazole derivatives, styrylanthracene derivatives, fluorenone derivatives, hydrazone derivatives, and silazane derivatives, while examples of high molecular ones include polymers of phenylenevinylene, fluorene, carbazole, indole, pyrene, pyrrole, picoline, thiophene, acetylene and diacetylene, and derivatives thereof. It is possible to use other compounds as far as they have sufficient hole transportability though they are not electron-donating compounds.

The thickness of the electron blocking layer is preferably from 10 nm to 200 nm, far preferably from 30 nm to 150 nm, particularly preferably from 50 nm to 100 nm. This is because, when this thickness is too thin, dark current suppression effect is lowered, while the photoelectric conversion efficiency is reduced when the thickness is too thick.

Examples of candidates for the electron blocking material include the materials represented by the following formulae.

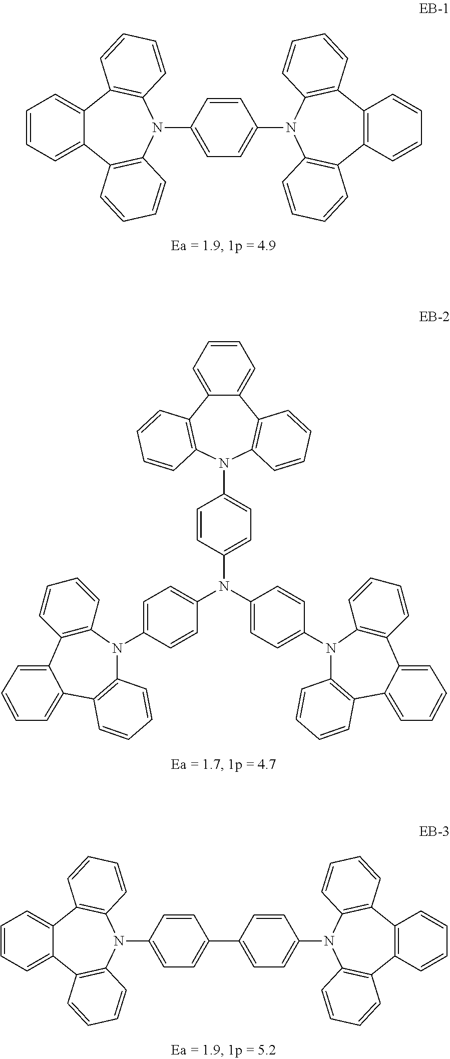 [SMILES: c1ccc2c(c1)-c1ccccc1N(c1ccc(N3c4ccccc4-c4ccccc4-c4ccccc43)cc1)c1ccccc1-2 ; c1ccc2c(c1)-c1ccccc1N(c1ccc(N(c3ccc(N4c5ccccc5-c5ccccc5-c5ccccc54)cc3)c3ccc(N4c5ccccc5-c5ccccc5-c5ccccc54)cc3)cc1)c1ccccc1-2 ; c1ccc2c(c1)-c1ccccc1N(c1ccc(-c3ccc(N4c5ccccc5-c5ccccc5-c5ccccc54)cc3)cc1)c1ccccc1-2]

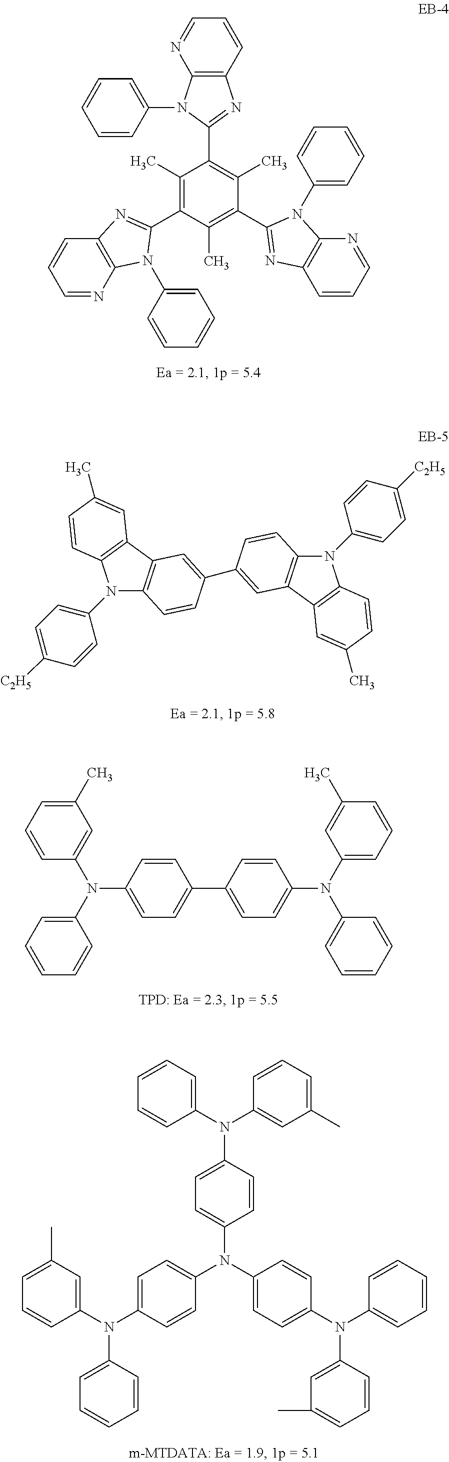 [SMILES: Cc1c(-c2nc3cccnc3n2-c2ccccc2)c(C)c(-c2nc3cccnc3n2-c2ccccc2)c(C)c1-c1nc2cccnc2n1-c1ccccc1 ; CCc1ccc(-n2c3ccc(C)cc3c3cc(-c4ccc5c(c4)c4cc(C)ccc4n5-c4ccc(CC)cc4)ccc32)cc1 ; Cc1cccc(N(c2ccccc2)c2ccc(-c3ccc(N(c4ccccc4)c4cccc(C)c4)cc3)cc2)c1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1]

As to materials practically usable in the electron blocking layer, the range of their choices is restricted by what materials are used for the adjacent electrode and the adjacent photoelectric conversion layer, respectively. Specifically, materials having an electron affinity (Ea) at least 1.3 eV greater than the work function (Wf) of a material used for the adjacent electrode and an ionization potential (Ip) equivalent to or smaller than the Ip of a material used for the adjacent photoelectric conversion layer are suitable as the materials used practically.

In accordance with this embodiment, the charge blocking layer or layers are designed to have a multiple-layer structure, not a single-layer structure currently in use, and thereby carrier injection from an electrode or electrodes into a photoelectric conversion layer under application of an external voltage can be inhibited and the photocurrent/dark current ratio of the photoelectric conversion element can be significantly enhanced.

### Second Embodiment

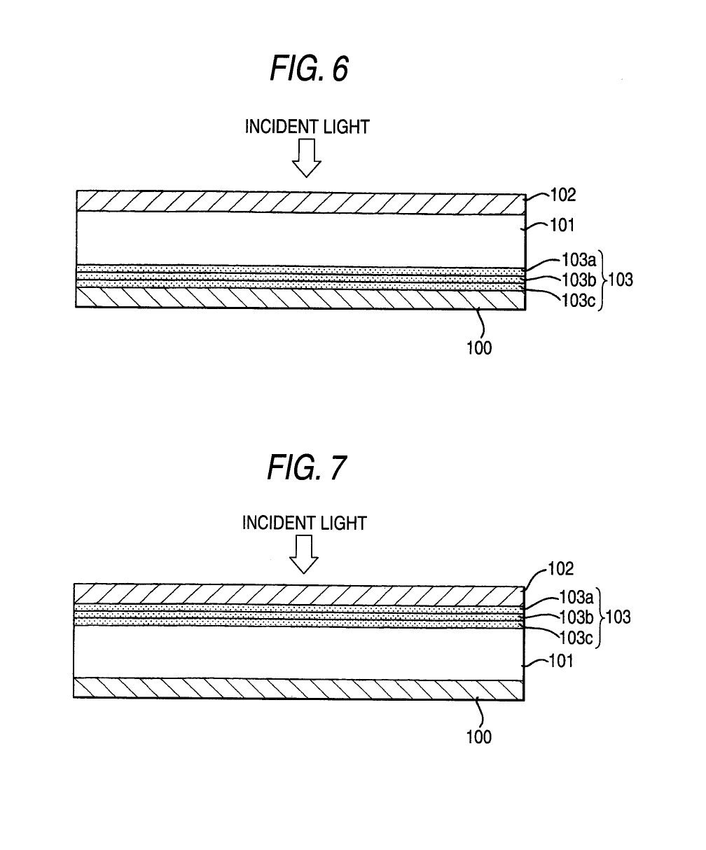

As to a second embodiment, examples of a photoelectric conversion element having a charge blocking layer of multiple-layer structure are illustrated by reference to FIG. 6 to FIG. 11.

There are two types of charge blocking layers—one being “a hole blocking layer” having a great barrier against hole injection from the adjacent electrode and high transport capacity of electrons as a photocurrent carrier, and one being “an electron blocking layer” having a great barrier against electron injection from the adjacent electrode and high transport capacity of holes as a photocurrent carrier. In organic luminescent elements, as disclosed in JP-A-11-339966 and JP-A-2002-329582, blocking layers using organic materials are already provided in order to prevent carriers from piercing through their respective luminescent layers. By inserting such an organic blocking layer between an electrode and a photoelectric conversion layer in a photoelectric conversion section, photoelectric conversion efficiency and response speed can be enhanced without attended by reduction in S/N ratio when an external voltage is applied.

In the hole blocking layer, materials having ionization potentials of no lower than the work function of a material of the adjacent electrode and electron affinity of no smaller than the electron affinity of a material of the adjacent photoelectric conversion layer can be used. In the electron blocking layer, materials having electron affinity of no greater than the work function of a material of the adjacent electrode and ionization potentials of no lower than the ionization potential of a material of the adjacent photoelectric conversion layer can be used. Examples of these materials include the same ones as recited for the first embodiment.

Now, the structures of photoelectric conversion elements including photoelectric conversion sections having those charge blocking layers are described in the concrete.

To begin with, the structures having hole blocking layers are illustrated.

FIG. 6 is a schematic cross-sectional diagram showing the outline of a makeup of a photoelectric conversion element according to this embodiment.

The photoelectric conversion element shown in FIG. 6 is configured to include a pair of opposed electrodes 100 and 102, and a photoelectric conversion section made up of a photoelectric conversion layer made from an organic material and formed between the electrode 100 and the electrode 102, and a hole blocking layer 103 formed between the photoelectric conversion layer 101 and the electrode 100.

As shown in the figure, the hole blocking layer 103 has a triple-layer structure in which material layers 103a to 103c are stacked on top of each other. As mentioned above, it is preferable that at least two of the material layers 103a to 103c are made from different materials, respectively. However, it will suffice for the present purpose that the hole blocking layer 103 has a multiple-layer structure.

It is preferred that the inorganic material is located on the boundary face of the electrode and the organic material is located on the inner side of the inorganic material, as the material layer 103c is of the inorganic material and the material layers 103a and 103b are of the organic material.

The photoelectric conversion element shown in FIG. 6 is configured so as to receive light incident from above its electrode 102, and the electrode 102 serves as an electrode on the side of light incidence. In addition, the photoelectric conversion element shown in FIG. 6 is configured so that, by application of a voltage between the electrodes 100 and 102, holes in charges (holes and electrons) developing in the photoelectric conversion layer 101 are transferred to the electrode 102 and electrons in the charges to the electrode 100 (in other words, the electrode 100 is employed as an electrode for taking out electrons).

As a material of the hole blocking layer 103, materials having ionization potentials of no lower than the work function of a material of the adjacent electrode 100 and electron affinity of no smaller than the electron affinity of a material of the adjacent photoelectric conversion layer 101 can be used. By providing this hole blocking layer 103 between the electrode 100 and the photoelectric conversion layer 101, not only electrons developing in the photoelectric conversion layer 101 when a voltage is applied between the electrodes 100 and 102 can be transferred to the electrode 100, but also injection of holes from the electrode 100 into the photoelectric conversion layer 101 can be suppressed. And the triple-layer structure given to the hole blocking layer 103 can heighten the effect of suppressing the injection of holes from the electrode 100 into the photoelectric conversion layer 101 via intermediate levels.

The best total thickness of the hole blocking layer 103 is from 10 nm to 200 nm. This is because too great a thickness of this layer, though can heighten blocking capacity, causes a drop in external quantum efficiency since there is a need to transfer electrons developing in the photoelectric conversion layer 101 to the electrode 100.

In addition, it is preferable that the value obtained by dividing a voltage externally applied between the electrodes 100 and 102 by the sum of a thickness of the hole blocking layer 103 and a thickness of the photoelectric conversion layer 101 (corresponding to the distance between the electrode 100 and the electrode 102) is from 1.0×10⁵ V/cm to 1.0×10⁷ V/cm.

Furthermore, since entry of light into the photoelectric conversion layer 101 is required of the photoelectric conversion element shown in FIG. 6, it is preferable that the electrode 102 is a transparent electrode. The term “transparent” as used herein refers to the state of allowing at least 80% of visible rays with wavelengths of about 420 nm to about 660 nm to pass through.

On the other hand, as mentioned below, there is a case where transmission of incident light to a region beneath the electrode 100 is also required in the photoelectric conversion element shown in FIG. 6, so it is preferable that the electrode 100 is a transparent electrode and the hole blocking layer 103 is also transparent.

FIG. 7 is a schematic cross-sectional diagram showing a variation of the photoelectric conversion element shown in FIG. 6.

When a voltage is applied between the electrodes 100 and 102 so that, of the charges (holes and electrons) developing in the photoelectric conversion layer 101 of the photoelectric conversion element as shown in FIG. 6, electrons are transferred to the electrode 102 and holes are transferred to the electrode 100 (in other words, the electrode 102 is made to act as an electrode for taking out electros), it is adequate to configure the photoelectric conversion element, as illustrated in FIG. 7, so that the hole blocking layer 103 (having a triple-layer structure in which the material layers 103a to 103c are stacked on top of each other) is provided between the electrode 102 and the photoelectric conversion layer 101. In this case, the hole blocking layer 103 is required to be transparent. By such a layer structure, dark current can be suppressed.

Additionally, as mentioned above, it becomes feasible to suppress a dark current more markedly and avoid inhibiting the reading of signal charges by giving the blocking layer such a structure that an inorganic material layer is disposed on the electrode surface and an organic material layer is sandwiched between the inorganic material layer and a photoelectric conversion layer, specifically by designing the material layer 103c in FIG. 6 as a layer including an inorganic material and the material layers 103a and 103b in FIG. 6 as layers including organic materials, or by designing the material layer 103a in FIG. 7 as a layer including an inorganic material and the material layers 103b and 103c in FIG. 7 as layers including organic materials.

Then, makeups including electron blocking layers are illustrated.

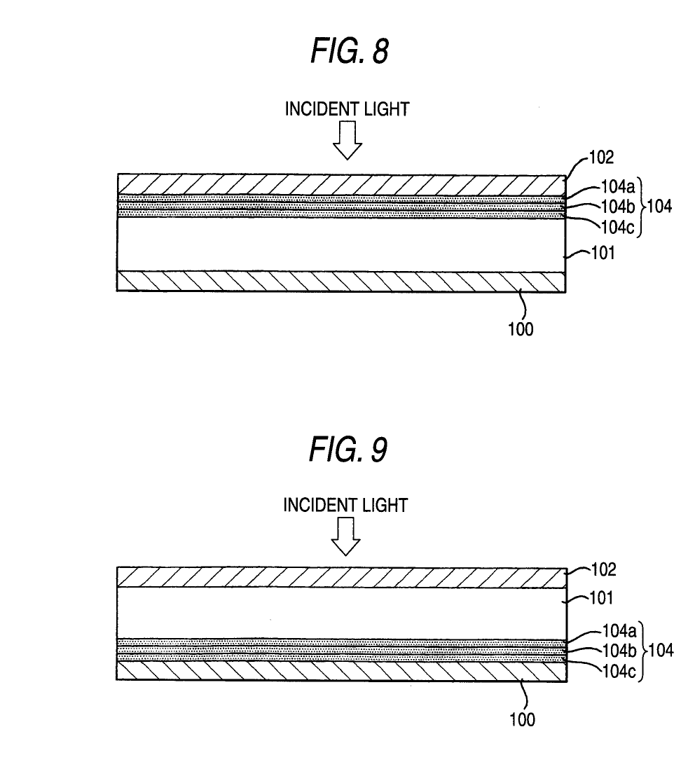

FIG. 8 is a schematic cross-sectional diagram showing the outline of a makeup of another photoelectric conversion element (a case where an electron blocking layer is provided) according to an embodiment of the invention. In FIG. 8, the same numerals and symbols as those in FIG. 6 are given to constituents having the same functions as in FIG. 6, respectively.

The photoelectric conversion element shown in FIG. 8 is configured so as to include a pair of opposed electrodes 100 and 102, and a photoelectric conversion section made up of a photoelectric conversion layer 101 formed between the electrode 100 and the electrode 102, and an electron blocking layer 104 (having a triple-layer structure in which material layers 104a to 104c are stacked on top of each other) formed between the photoelectric conversion layer 101 and the electrode 102. As mentioned above, it is preferable that at least two of the material layers 104a to 104c are made from different materials, respectively. However, it will suffice for the present purpose that the electron blocking layer 104 has a multiple-layer structure.

It is preferred that the inorganic material is located on the boundary face of the electrode and the organic material is located on the inner side of the inorganic material, as the material layer 104c is of the inorganic material and the material layers 104a and 104b are of the organic material.

The photoelectric conversion element shown in FIG. 8 is configured so as to receive light incident from above its electrode 102, and the electrode 102 serves as an electrode on the side of light incidence. In addition, the photoelectric conversion element shown in FIG. 8 is configured so that, by application of a voltage between the electrodes 100 and 102, holes in charges (holes and electrons) developing in the photoelectric conversion layer 101 are transferred to the electrode 102 and electrons in the charges to the electrode 100 (in other words, the electrode 100 is employed as an electrode for taking out electrons).

As a material of the electron blocking layer 104, materials having electron affinity of no greater than the work function of a material of the adjacent electrode 102 and ionization potential of no higher than the ionization potential of a material of the adjacent photoelectric conversion layer 101 can be used. By providing this electron blocking layer 104 between the electrode 102 and the photoelectric conversion layer 101, not only holes developing in the photoelectric conversion layer 101 when a voltage is applied between the electrodes 100 and 102 can be transferred to the electrode 102, but also injection of electrons from the electrode 102 into the photoelectric conversion layer 101 can be prevented.

The best total thickness of the electron blocking layer 104 is from 10 nm to 200 nm. This is because too great a thickness of this layer, though can heighten blocking capacity, causes a drop in external quantum efficiency since there is a need to transfer holes developing in the photoelectric conversion layer 101 to the electrode 102.

In addition, it is preferable that the value obtained by dividing a voltage externally applied between the electrodes 100 and 102 by the sum of a thickness of the electron blocking layer 104 and a thickness of the photoelectric conversion layer 101 (corresponding to the distance between the electrode 100 and the electrode 102) is from 1.0×10⁵ V/cm to 1.0×10⁷ V/cm.

Furthermore, since entry of light into the photoelectric conversion layer 101 is required of the photoelectric conversion element shown in FIG. 8, it is preferable that both the electrode 102 and the electron blocking layer 104 are transparent.

On the other hand, as mentioned below, there is a case where transmission of incident light to a region beneath the electrode 100 is also required for the photoelectric conversion element shown in FIG. 8, so it is preferable that the electrode 100 is also a transparent electrode.

FIG. 9 is a schematic cross-sectional diagram showing a variation of the photoelectric conversion element shown in FIG. 8.

When a voltage is applied between the electrodes 100 and 102 so that, of the charges (holes and electrons) developing in the photoelectric conversion layer 101 of the photoelectric conversion element as shown in FIG. 8, electrons are transferred to the electrode 102 and holes are transferred to the electrode 100 (in other words, the electrode 102 is made to act as an electrode for taking out electros), it is adequate to configure the photoelectric conversion element, as illustrated in FIG. 9, so that the electron blocking layer 104 is provided between the electrode 100 and the photoelectric conversion layer 101. By this makeup, dark current can be suppressed.

Additionally, as mentioned above, it becomes feasible to suppress a dark current more markedly and avoid inhibiting the reading of signal charges by giving the blocking layer such a structure that an inorganic material layer is disposed on the electrode surface and an organic material layer is sandwiched between the inorganic material layer and a photoelectric conversion layer, specifically by designing the material layer 104a in FIG. 8 as a layer including an inorganic material and the material layers 104b and 104c in FIG. 8 as layers including organic materials, or by designing the material layer 104c in FIG. 9 as a layer including an inorganic material and the material layers 104a and 104c in FIG. 9 as layers including organic materials.

Next, makeups each including an electron blocking layer and a hole blocking layer are illustrated.

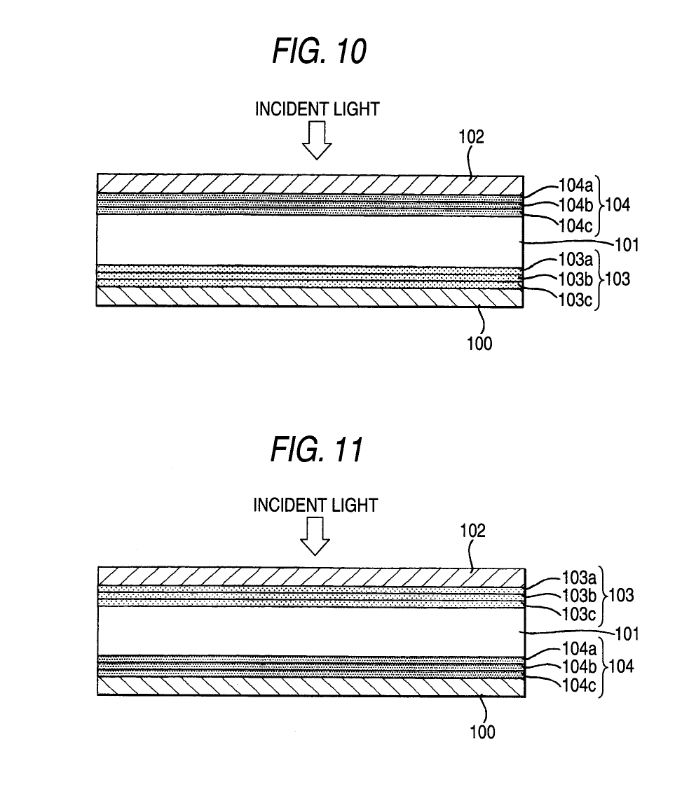

FIG. 10 is a schematic cross-sectional diagram showing the outline of a makeup of still another photoelectric conversion element (a case of having a photoelectric conversion section provided with both an electron blocking layer and a hole blocking layer) according to an embodiment of the invention. In FIG. 10, the same numerals and symbols as those in FIG. 6 or FIG. 8 are given to constituents having the same functions as in FIG. 6 or FIG. 8, respectively.

The photoelectric conversion element shown in FIG. 10 is configured so as to include a pair of opposed electrodes 100 and 102, and a photoelectric conversion section made up of a photoelectric conversion layer 101 formed between the electrode 100 and the electrode 102, a hole blocking layer 103 (103a to 103c) formed between the photoelectric conversion layer 101 and the electrode 100, and an electron blocking layer 104 (104a to 104c) formed between the photoelectric conversion layer 101 and the electrode 102.

The photoelectric conversion element shown in FIG. 10 is configured so as to receive light incident from above its electrode 102, and the electrode 102 serves as an electrode on the side of light incidence. In addition, the photoelectric conversion element shown in FIG. 10 is configured so that, by application of a voltage between the electrodes 100 and 102, holes in charges (holes and electrons) developing in the photoelectric conversion layer 101 are transferred to the electrode 102 and electrons in the charges to the electrode 100 (in other words, the electrode 100 is employed as an electrode for taking out electrons).

In addition, it is preferable that the value obtained by dividing a voltage externally applied between the electrodes 100 and 102 by the sum of a thickness of the hole blocking layer 103, a thickness of the electron blocking layer 104 and a thickness of the photoelectric conversion layer 101 (corresponding to the distance between the electrode 100 and the electrode 102) is from 1.0×10⁵ V/cm to 1.0×10⁷ V/cm.

In accordance with such a makeup, injection of charges from both electrodes 100 and 102 can be inhibited, and dark current can be suppressed effectively.

FIG. 11 is a schematic cross-sectional diagram showing a variation of the photoelectric conversion element shown in FIG. 10.

When a voltage is applied between the electrodes 100 and 102 so that, of the charges (holes and electrons) developing in the photoelectric conversion layer 101 of the photoelectric conversion element as shown in FIG. 10, electrons are transferred to the electrode 102 and holes are transferred to the electrode 100 (in other words, the electrode 102 is made to act as an electrode for taking out electros), it is adequate to configure the photoelectric conversion element, as illustrated in FIG. 11, so that the electron blocking layer 104 is provided between the electrode 100 and the photoelectric conversion layer 101, while the hole blocking layer 103 is provided between the electrode 102 and the photoelectric conversion layer 101.

Such a makeup also permits inhibition of charge injection from both electrodes 100 and 102, and effective suppression of dark current.

### Third Embodiment

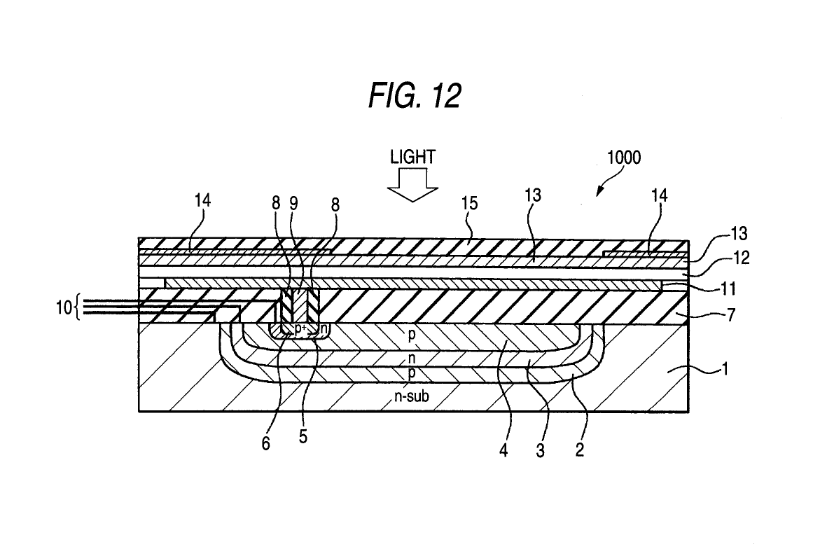

Examples of the makeup of a solid-state image pickup device using the photoelectric conversion element having the structure shown in FIG. 11 are illustrated below. In the following description, FIG. 12 to FIG. 16 are referred to. In each of these figures also, both the hole blocking layer and the electron blocking layer have multiple-layer structures as in the foregoing embodiments. However, each blocking layer in FIG. 12 to FIG. 16 is not drawn in the form of multiple-layer division in particular for convenience in drawing diagrams.

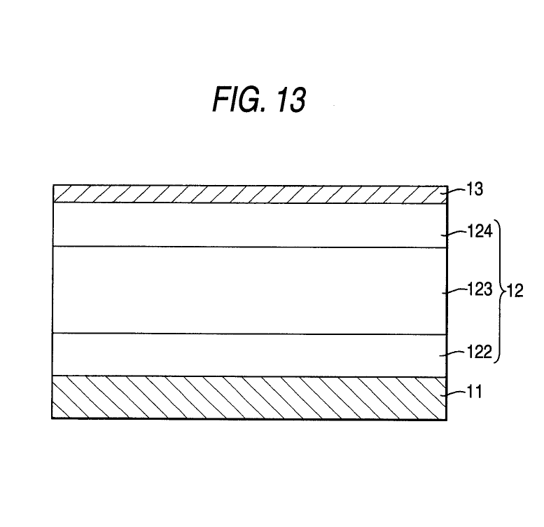

FIG. 12 is a schematic cross-sectional diagram of a pixel of solid-state image pickup device, which illustrates a third embodiment of the invention. FIG. 13 is a schematic cross-sectional view of the intermediate layer shown in FIG. 12. This solid-state image pickup device includes a large number of pixels, each of which is the pixel shown in FIG. 12, disposed in array on one plane, and signals obtained from this one pixel can produce one pixel of datum on image data.

A pixel of solid-state image pickup device shown in FIG. 12 is configured to include an n-type silicon substrate 1, a transparent insulation film 7 formed on the n-type silicon substrate 1 and a photoelectric conversion section having a first electrode film 11 formed on the insulation film 7, an intermediate layer 12 formed on the first electrode film 11 and a second electrode film 13 formed on the intermediate layer 12, and on the photoelectric conversion section a light-shielding film 14 with an aperture is further formed. By this light-shielding film 14, a limitation is imposed on the photoreceptive area of the intermediate layer 12. In addition, a transparent insulation film 15 is formed on the light-shielding film 14 and the second electrode film 13. Additionally, the makeup of the photoelectric conversion element described in the first or second embodiment of the invention can be applied to the photoelectric conversion section formed on the insulation film 7.

As shown in FIG. 13, the intermediate layer 12 is so configured that the first electrode film 11, a subbing-cum-electron-blocking layer 122, a photoelectric conversion layer 123 and a hole-blocking-cum-buffering layer 124 are stacked on top of each other in order of mention. Each of the electron-blocking layer 122 and the hole-blocking-cum-buffering layer 124 is made up of a plurality of layers as described in the first and second embodiments of the invention.

The photoelectric conversion layer 123 is made up in a state of containing a material having such properties as to develop charges including electrons and holes in response to light incident from above of the second electrode film 13, render electron mobility smaller than hole mobility, and develop more electrons and more holes in the vicinity of the second electrode film 13 than in the vicinity of the first electrode film 11. Representative examples of such a material for use in the photoelectric conversion film are organic materials. In the makeup shown in FIG. 12, a material capable of absorbing green light and developing electrons and holes in response to the green light absorbed is used for the photoelectric conversion layer 123. The photoelectric conversion layer 123 can be shared by all pixels, so it may be made up of one sheet of film, and doesn't need to be kept separated for each pixel.

An organic material constituting the photoelectric conversion layer 123 preferably includes at least either organic p-type semiconductor or organic n-type semiconductor. As the organic p-type and n-type semiconductors, any of quinacridone derivatives, naphthalene derivatives, anthracene derivatives, phenanthrene derivatives, tetracene derivatives, pyrene derivatives, perylene derivatives and fluoranthene derivatives can be used to particular advantage.

The organic p-type semiconductors (compounds) are organic semiconductors (compounds) capable of acting as donors, and refer to organic compounds having the property of easily donating electrons, typified mainly by hole-transporting organic compounds. More specifically, when two organic materials are used in contact with each other, the organic material smaller in ionization potential is referred to as an organic p-type semiconductor. Accordingly, any of organic compounds having electron-donating properties is usable as the organic donor compound. Examples of an organic compound usable as the organic donor compound include triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonol compounds, polyamine compounds, indole compounds, pyrrole compounds, pyrazole compounds, polyarylene compounds, aromatic condensed carbon-ring compounds (including naphthalene derivatives, anthracene derivatives, phenanthrene derivatives, tetracene derivatives, pyrene derivatives and fluoranthene derivatives), and metal complexes having nitrogen-containing hetero ring compounds as ligands. Additionally, as mentioned above, the compounds usable as organic donor compounds are not limited to those recited above, but may be any organic compounds as far as their ionization potentials are smaller than those of the organic compounds used as n-type (acceptor) compounds.

The organic n-type semiconductors (compounds) are organic semiconductors (compounds) capable of acting as acceptors, and refer to organic compounds having the property of easily accepting electrons, typified mainly by electron-transporting organic compounds. More specifically, when two organic compounds are used in contact with each other, the organic compound greater in electron affinity is referred to as an organic n-type semiconductor. Accordingly, any of organic compounds having electron-accepting properties is usable as the organic acceptor compound. Examples of an organic compound usable as the organic acceptor compound include condensed aromatic carbon-ring compounds (such as naphthalene derivatives, anthracene derivatives, phenanthrene derivatives, tetracene derivatives, pyrene derivatives, perylene derivatives and fluoranthene derivatives), 5- to 7-membered nitrogen-, oxygen- or/and sulfur-containing heterocyclic compounds (such as pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrqazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyralidine, pyrrolopyridine, thiadiazolopyridine, dibenzazepine and tribenzazepine), polyarylene compounds, fluorene compounds, cyclopentadiene compounds, silyl compounds, and metal complexes having nitrogen-containing heterocyclic compounds as ligands. Additionally, as mentioned above, the compounds usable as organic acceptor compounds are not limited to those recited above, but may be any organic compounds as far as their electron affinities are greater than those of the organic compounds used as donor compounds.

As p-type organic dyes or n-type organic dyes, any dyes may be used, but examples of preferred dyes include cyanine dyes, styryl dyes, hemicyanine dyes, merocyanine dyes (including a zero-methine merocyanine (simple merocyanine)), trinuclear merocyanine dyes, tetranuclear merocyanine dyes, rhodacyanine dyes, complex cyanine dyes, complex merocyanine dyes, allopolar dyes, oxonol dyes, hemioxonol dyes, squarylium dyes, croconium dyes, azamethine dyes, coumarin dyes, arylidene dyes, anthraquinone dyes, fluorenone dyes, flugide dyes, perylene dyes, phenazine dyes, phenothiazine dyes, quinone dyes, indigo dyes, diphenylmethane dyes, polyene dyes, acridine dyes, acridinone dyes, diphenylamine dyes, quinacridone dyes, quinophthalone dyes, phenoxazine dyes, phthaloperylene dyes, porphyrin dyes, chlorophyll dyes, phthalocyanine dyes, metal complex dyes, and aromatic fused carbon-ring series dyes (such as naphthalene derivatives, anthracene derivatives, phenanthrene derivatives, tetracene derivatives, pyrene derivatives, perylene derivatives and fluoranthene derivatives).

Then, the metal complex compounds are described. Each of the metal complex compounds is a metal complex having at least one nitrogen-, oxygen- or sulfur-containing ligand that coordinates with metal, and the metal ion in the metal complex has no particular restriction, but it is preferably a beryllium ion, a magnesium ion, an aluminum ion, a gallium ion, a zinc ion, an indium ion or a tin ion, far preferably a beryllium ion, an aluminum ion, a gallium ion or a zinc ion, further preferably an aluminum ion or a zinc ion. As ligands contained in the metal complexes, there are already known a wide variety of ligands. Examples thereof include the ligands described, e.g., in H. Yersin, Photochemistry and Photophysics of Coordination Compounds, Springer-Verlag (1987) and Akio Yamamoto, Yuki Kinzoku Kagaku—Kiso to Oyo—, Shokabo Publishing Ltd. (1982).

The ligand is preferably a nitrogen-containing hetero ring ligand (which contains preferably 1 to 30 carbon atoms, far preferably 2 to 20 carbon atoms, particularly preferably 3 to 15 carbon atoms, and may be a unidentate or bidentate ligand, preferably a bidentate ligand, with examples including a pyridine ligand, a bipyridyl ligand, a quinolinol ligand, hydroxyphenylazole ligands (such as a hydroxyphenylbenzimidazole ligand, a hydroxyphenylbenzoxazole ligand and a hydroxyphenylimidazole ligand), an alkoxy ligand (which contains preferably 1 to 30 carbon atoms, far preferably 1 to 20 carbon atoms, particularly preferably 1 to 10 carbon atoms, with examples including methoxy, ethoxy, butoxy and 2-ethylhexyloxy ligands), an aryloxy ligand (which contains preferably 6 to 30 carbon atoms, far preferably 6 to 20 carbon atoms, particularly preferably 6 to 12 carbon atoms, with examples including phenyloxy, 1-naphthyloxy, 2-naphthyloxy, 2,4,6-trimethylphenyloxy and 4-biphenyloxy ligands), a heteroaryloxy ligand (which contains preferably 1 to 30 carbon atoms, far preferably 1 to 20 carbon atoms, particularly preferably 1 to 12 carbon atoms, with examples including pyridyloxy, pyradinyloxy, pyrimidyloxy and quinolyloxy ligands), an alkylthio ligand (which contains preferably 1 to 30 carbon atoms, far preferably 1 to 20 carbon atoms, particularly preferably 1 to 12 carbon atoms, with examples including methylthio and ethylthio ligands), an arylthio ligand (which contains preferably 6 to 30 carbon atoms, far preferably 6 to 20 carbon atoms, particularly preferably 6 to 12 carbon atoms, such as a phenylthio ligand), a heterocyclylthio ligand (which contains preferably 1 to 30 carbon atoms, far preferably 1 to 20 carbon atoms, particularly preferably 1 to 12 carbon atoms, with examples including pyridylthio, 2-benzimidazolylthio, 2-benzoxazolylthio and 2-benzothiazolylthio ligands) or a siloxy ligand (which contains preferably 1 to 30 carbon atoms, far preferably 3 to 25 carbon atoms, particularly preferably 6 to 20 carbon atoms, with examples including triphenylsiloxy, triethoxysiloxy and triisopropylsiloxy ligands), far preferably a nitrogen-containing hetero ring ligand, an aryloxy ligand, a heteroaryloxy ligand or a siloxy ligand, further preferably a nitrogen-containing hetero ring ligand, an aryloxy ligand or a siloxy ligand.

The intermediate layer 12 has a p-type semiconductor layer and an n-type semiconductor layer, and a case is suitable where at least either the p-type semiconductor or the n-type semiconductor is an organic semiconductor, and between those semiconductor layers is interposed a photoelectric conversion layer having as an intermediate layer a bulk heterojunction structural layer containing the p-type semiconductor and the n-type conductor. In this case, the incorporation of a bulk heterojunction structure into the intermediate layer 12 can alleviate a defect that the carrier diffusion length is short in the photoelectric conversion layer 123, and thereby can heighten the photoelectric conversion efficiency of the photoelectric conversion layer 123. Additionally, there is a detailed description of the bulk heterojunction structure in Japanese Patent Application No. 2004-080639.

And a case is preferable where the intermediate layer 12 includes a photoelectric conversion layer comprising a structure having pn-junction-layer repetition structures (tandem structures) wherein each layer is formed of a layer of a p-type semiconductor and a layer of an n-type semiconductor and the number of repetition structures is 2 or more, and a case is far preferable where a thin layer of conductive material is inserted between the repetition structures. The number of pn-junction-layer repetition structures (tandem structures) may be any value, but in order to enhance the photoelectric conversion efficiency the value is preferably from 2 to 50, far preferably from 2 to 30, particularly preferably 2 to 10. The conductive material is preferably silver or gold, especially preferably silver. There is a detailed description of the tandem structure in Japanese Patent Application No. 2004-079930.

In addition, a case is preferable where the photoelectric conversion layer included in the intermediate layer 12 has a layer of a p-type semiconductor and a layer of an n-type semiconductor (preferably a mixed and dispersed (bulk heterojunction structure) layer and contains an organic compound having undergone orientation control in at least either the p-type semiconductor or the n-type semiconductor, and a case is preferable by far where (possible) organic compounds having undergone orientation control are incorporated into both the p-type semiconductor and the n-type semiconductor, respectively. As those organic compounds, compounds having conjugated π electrons are suitably used. The alignment angle of the π-electron planes with respect to the substrate (electrode substrate) is not perpendicular, but the nearer to an angle comparable to parallel the alignment angle, the better the result obtained. The angle which each aligned plane forms with the substrate is preferably from 0° to 80°, far preferably from 0° to 60°, further preferably from 0° to 20°, particularly preferably from 0° to 10°, and the alignment angle of 0° (parallel to the substrate) is the best. The layers of organic compounds whose orientations are controlled as mentioned above may constitute at least a part of the whole intermediate layer 12. Specifically, the percentage of the orientation-controlled portion in the whole intermediate layer 12 is preferably at least 10%, far preferably at least 30%, further preferably at least 50%, furthermore preferably at least 70%, particularly preferably at least 90%. And the best proportion therein is 100%. These conditions, in which orientations of organic compounds contained in the intermediate layer 12 are controlled, permit alleviation of a defect that the carrier diffusion length is short in the photoelectric conversion layer, and thereby enhance the photoelectric conversion efficiency of the photoelectric conversion film.

In the case where the orientations of organic compounds are controlled, it is far preferable that the heterojunction faces (e.g., pn-junction faces) are not parallel to the substrate. Herein, it is more advantageous that the heterojunction faces are aligned at an angle nearer to square, but not parallel, to the substrate. The alignment angle to the substrate is preferably from 10° to 90°, far preferably from 30° to 90°, further preferably from 50° to 90°, furthermore preferably from 70° to 90°, particularly preferably from 80° to 90°. Herein, the best alignment angle is 90° (namely, square to the substrate). The organic compound layer(s) whose heterojunction faces are controlled as described above may constitute at least a part of the whole intermediate layer 12. Specifically, the percentage of the alignment-controlled portion in the whole intermediate layer 12 is preferably at least 10%, far preferably at least 30%, further preferably at least 50%, furthermore preferably at least 70%, particularly preferably at least 90%. And the best proportion therein is 100%. In these cases, the area of the heterojunction faces in the intermediate layer 12 is increased and the amount of carriers developing at interfaces, including electrons, holes and electron-hole pairs, is increased; as a result, enhancement of photoelectric conversion efficiency becomes possible. The photoelectric conversion layer in which alignments of organic compounds with respect to both their heterojunction faces and π-electron planes are controlled as described above can be especially improved in photoelectric conversion efficiency. As to these situations, there is a detailed description in Japanese Patent Application No. 2004-079931. Although the greater thickness of an organic dye layer is more favorable in point of light absorption, the suitable thickness of an organic dye layer in consideration of the percentage of a portion having no contribution to charge separation is from 30 nm to 300 nm, preferably from 50 nm to 250 nm, particularly preferably from 80 nm to 200 nm.

The intermediate layer 12 containing those organic compounds is formed into a film in accordance with a dry coating method or a wet coating method. Examples of a dry coating method usable herein include physical vapor-growth methods, such as a vacuum evaporation method, a sputtering method, an ion plating method and a MBE method, and CVD methods such as plasma polymerization. Examples of a wet coating method usable herein include a cast method, a spin coating method, a dipping method and an LB method.

In the case of using a high-molecular compound as at least either a p-type semiconductor (compound) or an n-type semiconductor (compound), it is preferable to form a film by use of a wet coating method which allows easy formation of film. When a dry coating method like vapor deposition is adopted, a high polymer is difficult to use because of a fear of decomposition, but its oligomer can be used favorably instead. On the other hand, it is preferable to adopt a dry coating method, especially a vacuum evaporation method, when a low-molecular compound is used. The basic parameters in the vacuum evaporation method include the method adopted in heating a compound, which is chosen from resistance heating, electron-beam heating or so on, the shape of an evaporation source such as a crucible or a boat, the degree of vacuum, the evaporation temperature, the base temperature and the evaporation speed. In order to ensure uniform evaporation, it is advantageous to perform the evaporation while rotating the base. As to the degree of vacuum, the higher the better. Specifically, the vacuum evaporation is performed under a pressure of 10⁻⁴ Torr or less, preferably 10⁻⁶ Torr or less, particularly preferably 10⁻⁸ Torr or less. The compound is basically kept from direct contact with oxygen and moisture in outside air. Strict control of the aforesaid conditions for vacuum evaporation are required since those conditions have effects on the crystallinity, amorphous state, density and compactness of an organic film to be formed. It is advantageous to adopt PI control or PID control of the evaporation speed which is exercised with a film thickness monitor such as a quartz oscillator or an interferometer. When two or more kinds of compounds are evaporated at the same time, a co-evaporation method or a flash evaporation method can be used to advantage.

When light is incident from above the second electrode 13 in the makeup mentioned above, electrons and holes developing by light absorption in the photoelectric conversion layer 123 including organic materials are generally large in number in the vicinity of the second electrode 13 and not so large in number in the vicinity of the first electrode 11. This is ascribable to a phenomenon that most of light with wavelengths in the neighborhood of the absorption peak of the photoelectric conversion layer 123 are absorbed in the vicinity of the second electrode 13 and the rate of light absorption decreases with increasing distance from the second electrode 13. Therefore, unless electrons and holes developing in the vicinity of the second electrode 13 are transferred with efficiency into the silicon substrate, reduction in photoelectric conversion efficiency is caused to result in the element's sensitivity being lowered. In addition, signals based on the wavelengths of light strongly absorbed in the vicinity of the second electrode 13 are reduced to result in the broadening of the width of spectral sensitivities.

Furthermore, it is general in the photoelectric conversion layer 123 including organic materials that the mobility of electrons is much smaller than that of holes. Additionally, the mobility of electrons in the photoelectric conversion layer 123 including organic materials is susceptible to oxygen, and it is known that exposure of the photoelectric conversion layer to the air causes a drop in mobility of electrons. Therefore, when the travel of electrons to the silicon substrate 1 is intended, a long travel distance of electrons developing in the vicinity of the second electrode 13 through the photoelectric conversion layer 123 makes part of electrons lose their activity during the travel, and these deactivated electrons are not collected by the electrode. As a result, the sensitivity is lowered and the spectral sensitivity is broadened.

For preventing the sensitivity from lowering and the spectral sensitivity from broadening, it is effective to move electrons or holes developing in the vicinity of the second electrode 13 into the silicon substrate 1 with efficiency. In order to achieve such a movement, how to manage the electrons or holes developing in the photoelectric conversion layer 123 becomes a problem.

The solid-state image pickup element 1000 is provided with the photoelectric conversion layer 123 having the characteristics described above, so it collects holes in the first electrode film 11 as an electrode opposite to the electrode on the side of light incidence and utilizes them as described above. By doing so, the solid-state image pickup element 1000 can raise its external quantum efficiency, and can have an increased sensitivity and a sharpened spectral sensitivity distribution. In the solid-state image pickup element 1000, a voltage is therefore applied between the first electrode film 11 and the second electrode film 13 so that electrons developing in the photoelectric conversion layer 123 travel to the second electrode film 13 and holes developing in the photoelectric conversion layer 123 travel to the first electrode film 11.

One function of the subbing-cum-electron-blocking layer 122 consists in moderation of asperities on the first electrode film 11. When the first electrode film 11 has asperities on its surface or dust is deposited on the first electrode film 11, formation of a photoelectric conversion layer 123 by evaporation of a low molecular-weight organic compound onto the electrode film in such a condition tends to cause a trouble that the photoelectric conversion layer 123 produces fine cracks in the areas on those asperities, namely the photoelectric conversion layer 123 is liable to have areas formed in a state of merely thin film. When the second electrode film 13 is further formed on the photoelectric conversion layer in such a situation, the cracked areas are covered with the second electrode film 13 and become a cause of the proximity of the two electrode films. Therefore, DC shorts and an increase in leak current tend to occur. This tendency is remarkable in the case of using TCO in particular as the second electrode film 13. Accordingly, the occurrence of those troubles can be controlled by providing a subbing film-cum-electron-blocking layer 122 on the first electrode film 11 in advance and moderating asperities on the electrode film.

To be a uniform and smooth film is of importance with the subbing film-cum-electron-blocking layer 122. Examples of a material suitable for formation of smooth film in particular include organic polymeric materials, such as polyaniline, polythiophene, polypyrrole, polycarbazole, PTPDES and PTPDEK, and such film can also be formed according to a spin coating method.

The electron-blocking layer 122 is provided for the purpose of reducing a dark current traceable to electron injection from the first electrode film 11, and blocks the injection of electrons from the first electrode film 11 into the photoelectric conversion layer 123.

The hole-blocking-cum-buffering layer 125 is provided with the intention of reducing a dark current traceable to hole injection from the second electrode film 13 when acts as a hole-blocking layer, and performs not only a function of blocking the injection of holes from the second electrode 13 into the photoelectric conversion layer 123 but also, in some cases, a function of lessening a damage to the photoelectric conversion layer 123 during the formation of the second electrode film 13.

When the second electrode film 13 is formed as the upper layer of the photoelectric conversion layer 123, there may be cases where high energy particles present in an apparatus used for formation of the second electrode film 13, such as sputter particles, secondary electrons, Ar particles and oxygen anions which are produced by adoption of a sputtering method, collide with the photoelectric conversion layer 123 to result in spoilage of the photoelectric conversion layer and degradation of performance, such as an increase in leak current and a decrease in sensitivity. As a method of preventing such degradation, it is suitable to provide the buffering layer 125 on the photoelectric conversion layer 123.

Let's go back to FIG. 12. Inside the n-type silicon substrate 1, a p-type semiconductor zone 4 (hereinafter abbreviated as “p zone 4”), an n-type semiconductor zone 3 (hereinafter abbreviated as “n zone 3”) and a p-type semiconductor zone 2 are formed in increasing order of depth. In the p zone 4, a high-density p zone (referred to as an p⁺ zone) 6 is formed in a surface part of the area shaded by the light-shielding film 14 and the p⁺ zone 6 is surrounded by a n zone 5.

The depth of the pn junction face between the p zone 4 and the n zone 3 from the surface of the m-type silicon substrate 1 is adjusted to the blue-light absorption depth (about 0.2 μm). Accordingly, the p zone 4 and the n zone 3 form a photodiode (B photodiode) in which blue light is absorbed and holes are produced in response to the light absorbed, and stored. The holes produced in the B photodiode are stored in the p zone 4.

The depth of the pn junction face between the p zone 2 and the n-type silicon substrate 1 from the surface of the n-type silicon substrate 1 is adjusted to the red-light absorption depth (about 2 μm). Accordingly, the p zone 2 and the n-type silicon substrate 1 form a photodiode (R photodiode) in which red light is absorbed and holes are produced in response to the light absorbed, and stored. The holes produced in the R photodiode are stored in the p zone 2.

The p⁺ zone 6 is electrically connected to the first electrode film 11 via a connecting section 9 formed in an aperture piercing through an insulating film 7, and stores the holes collected by the first electrode film 11 via the connecting section 9. The connecting section 9 is electrically insulated by an insulation film 8 from members other than the first electrode film 11 and the p⁺ zone 6.

The holes stored in the p zone 2 are converted into signals responsive to their charge quantity by means of a MOS circuit made up of p-channel MOS transistors (not illustrated in the figure) formed inside the n-type silicon substrate 1, the holes stored in the p zone 4 are converted into signals responsive to their charge quantity by means of a MOS circuit made up of p-channel MOS transistors (not illustrated in the figure) formed inside the n zone 3, and the electrons stored in the p⁺ zone 6 are converted into signals responsive to their charge quantity by means of a MOS circuit made up of p-channel MOS transistors (not illustrated in the figure) formed inside the p zone 5. All of these signals are output to the outside of the solid-state image pickup element 1000. These MOS circuits constitute a signal readout section included in the scope of a claimed aspect of the invention. Each MOS circuit is connected to a signal readout pad not illustrated in the figure by means of wiring 10. Additionally, the p zone 2 and the p zone 4 are equipped with extraction electrodes and, when a designated reset voltage is applied thereto, each zone is brought into depletion, and the capacity of each pn junction area becomes closer and closer to the smallest value. Thus, the capacity developing at each junction face can be minimized.

The makeup as mentioned above permits photoelectric conversion of green light (G light) in the photoelectric conversion layer 123, and photoelectric conversion of blue light (B light) and red light (R light) by the B photodiode and R photodiode, respectively, in the n-type silicon substrate. Since G light is absorbed first in the upper part, this makeup delivers excellent B-G and G-R color separations. This is a point far superior to a solid-state image pickup element of the type which performs separation of B light, G light and R light inside the silicon substrate where three photodiodes (PDs) are stacked on top of each other. In the following descriptions, the portions for performing photoelectric conversion which are made up of inorganic materials (B photodiode and R photodiode) and formed insides the n-type silicon substrate 1 of the solid-state image pickup element 1000 are referred to as inorganic layers, too.

Additionally, it is also possible to form between the n-type silicon substrate 1 and the first electrode film 11 (e.g., between the insulation film 7 and the n-type silicon substrate 1) an inorganic photoelectric conversion portion made up of inorganic materials which absorb light transmitted by the photoelectric conversion layer 123, generate charges responsive to the light absorbed and store the charges. In this case, a MOS circuit for readout of signals responsive to the charges stored in a charge storage zone of the inorganic photoelectric conversion portion may be provided inside the n-type silicon substrate 1, and the wiring 10 may be connected to this MOS circuit also.

The first electrode film 11 has a function of collecting holes which are generated in the photoelectric conversion layer 123, and move to and arrive at the first electrode 11. The first electrode film 11 is provided separately for each pixel, and thereby image data can be produced. In the makeup shown in FIG. 12, the n-type silicon substrate 1 also performs photoelectric conversion, so it is appropriate that the first electrode film 11 have a visible light transmittance of 60% or above, preferably 90% or above. When no photoelectric conversion region is present underneath the first electrode film 11, the first electrode film 11 may be low in transparency. As a material of the first electrode 11, any material chosen from ITO, IZO, ZnO₂, SnO₂, TiO₂, FTO, Al, Ag or Au can be most suitably used. Details of the first electrode film 11 are described hereinafter.

The second electrode film 13 performs a function of discharging electrons which are generated in the photoelectric conversion layer 123, and move to and arrived at the second electrode film 13. The second electrode film 13 is shared by all pixels. So, in the solid-state image pickup device 1000, the second electrode film 13 is formed of one sheet of film utilized in common by all pixels. Since the second electrode film 13 is required to transmit the light incident thereon to the photoelectric conversion layer 123, it is appropriate to use a material having a high visible-light transmittance for formation of the second electrode film 13. The visible light transmittance of the second electrode film 13 is preferably 60% or above, far preferably 90% or above. As a material of the second electrode 13, any material chosen from ITO, IZO, ZnO₂, SnO₂, TiO₂, FTO, Al, Ag or Au can be most suitably used. Details of the second electrode film 13 are described hereinafter.

In the inorganic layer, the pn junction or pin junction of a compound semiconductor, such as crystalline silicon, amorphous silicon or GaAs, is generally used. In this case, as color separation is made according to the depth of light penetrating into silicon, the spectrum range detected by each of light-receiving segments stacked on top of one another becomes broad. However, as shown in FIG. 12, by using the photoelectric conversion layer 123 as the upper layer, or equivalently, by detecting the light having passed through the photoelectric conversion layer 123 in the depth direction of the silicon, color separation is significantly improved. As also shown in FIG. 12, when G light in particular is detected in the photoelectric conversion layer 123, light transmitted by the photoelectric conversion layer 123 comes to include B light and R light, so separation of light in the depth direction of the silicon is made only between B light and R light; as a result, color separation is improved. Even when B light or R light is detected in the photoelectric conversion layer, color separation can be markedly improved by adjusting the depths of pn junction faces in the silicon as appropriate.

The inorganic layer is preferably made up of npn or pnpn in the order from the side of light incidence. Since the surface potential can be kept high by providing a p-layer in particular at the surface and thereby holes and dark current generated in the vicinity of the surface can be trapped to result in reduction of dark current, the pnpn junction is preferable by far.

Incidentally, although FIG. 12 shows the makeup in which the photoelectric conversion section is disposed in one layer above the n-type semiconductor substrate 1, it is also possible to design so that the photoelectric conversion sections are stacked in two or more layers. The makeup in which the photoelectric conversion sections are staked in two or more layers is described hereinafter as an example set forth below according to the invention. In the case of such a makeup, the light detected in the inorganic layer may be light of one color, and favorable color separation can be achieved. When detection of four-color light is intended by means of one pixel of the solid-state image pickup element 1000, the following designs, for example, are further conceivable: in one design, one color is detected in one photoelectric conversion section and three colors are detected in the inorganic layer; in another design, the photoelectric conversion sections are staked in two layers and therein two colors are detected, and other two colors are detected in the inorganic layer; and in still another design, the photoelectric conversion sections are stacked in three layers and therein three colors are detected, and the rest is detected in the inorganic layer. On the other hand, the solid-state image pickup element 1000 may be configured to detect only one color per pixel. In this case, the p zone 2, the n zone 3 and the p zone 4 in FIG. 1 are omitted.

The inorganic layer is described in further detail. Suitable examples of a makeup of the inorganic layer include photoreceptive elements of photoconduction type, p-n junction type, Schottky junction type, PIN junction type and MSM (metal-semiconductor-metal) type, and photoreceptive elements of phototransistor type. It is especially advantageous to use an inorganic layer formed inside the single semiconductor substrate so that, as shown in FIG. 12, zones of first conduction type and zones of second conduction type which exhibiting conductivity opposite to the first conduction type are stacked alternately on top of each other, and each junction face between the zones of first and second conduction types is formed at a depth suitable for mainly achieving photoelectric conversion of light in each individual wavelength range chosen from two or more different wavelength ranges. As the single semiconductor substrate, single-crystal silicon is used to advantage, and color separation can be performed by utilizing its absorption wavelength characteristic depending on the depth direction of silicon substrate.

As an inorganic semiconductor, it is also possible to use an InGaN, InAlN, InAlP or InGaAlP system of inorganic semiconductor. The InGaN system of inorganic semiconductor is adjusted so as to have its absorption maximum within the wavelength range of blue light by altering the In content therein as appropriate. Specifically, it is altered to have a composition InₓGa₁₋ₓN (0≦X<1). Such a compound semiconductor can be produced by use of a metal-organic chemical vapor deposition method (MOCVD method). The InAlN system as a nitride semiconductor using Al belonging to the same group III as Ga can also be used as a short-wavelength photoreceptive portion as in the case of the InGaN system. Alternatively, InAlP and InGaAlP making a lattice match to a GaAs substrate can be also used.

Such an inorganic semiconductor may have an embedded structure. The term “embedded structure” as used herein means a structure in which both ends of a short-wavelength photoreceptor portion are covered with a semiconductor different from the short-wavelength photoreceptor. As the semiconductor covering the both ends, a semiconductor having a band gap wavelength shorter than or equal to the band gap wavelength of the short-wavelength photoreceptor portion is suitable.

As materials for the first electrode film 11 and the second electrode film 13, metals, alloys, metal oxides, electrically conductive compounds or mixtures of these substances can be used. Examples of a metallic material usable therein include combinations of elements selected arbitrarily from the group consisting of Li, Na, Mg, K, Ca, Rb, Sr, Cs, Ba, Fr, Ra, Sc, Ti, Y, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Al, Ga, In, Tl, Si, Ge, Sn, Pb, P, As, Sb, Bi, Se, Te, Po, Br, I, At, B, C, N, F, O and S. The preferred among them are Al, Pt, W, Au, Ag, Ta, Cu, Cr, Mo, Ti, Ni, Pd and Zn.

With the first electrode film 11 extracting and collecting holes from a hole-transportable photoelectric conversion layer or a hole-transporting layer included in the intermediate layer 12, materials for the electrode film 11 are selected with consideration given to adhesiveness to adjacent layers, such as a hole-transportable photoelectric conversion layer and a hole-transporting layer, electron affinity, ionization potential and stability. On the other hand, as the second electrode film 13 extracts electrons from an electron-transportable photoelectric conversion layer or an electron-transporting layer included in the intermediate layer 12 and discharges those electrons, materials for the electrode film 13 are selected with consideration given to adhesiveness to adjacent layers such as an electron-transportable photoelectric conversion layer and an electron-transporting layer, electron affinity, ionization potential and stability. Examples of those materials include conductive metal oxides such as tin oxide, zinc oxide, indium oxide and indium tin oxide (ITO), metals such as gold, silver, chromium and nickel, mixtures or laminated composites of those metals and conductive metal oxides, inorganic conductive substances such as copper iodide and copper sulfide, organic conductive materials such as polyaniline, polythiophene and polypyrrole, silicon compounds, and laminated composites of silicon compounds and ITO. Of these materials, conductive metal oxides are preferred over the others, and ITO and IZO in particular are used to advantage in point of productivity, high conductivity and transparency.

Methods for making electrodes vary with materials used. In the case of, say, ITO, film formation is performed using a method such as an electron beam method, a sputtering method, a resistance heating evaporation method, a chemical reaction method (sol-gel method), or a method of applying a dispersion of indium tin oxide. The ITO film can undergo UV-ozone treatment or plasma treatment.

Conditions under which a transparent electrode film is formed are mentioned below. The temperature of a silicon substrate under formation of a transparent electrode film is preferably 500° C. or below, far preferably 300° C. or below, further preferably 200° C. or below, still further preferably 150° C. or below. In addition, gas may be introduced during the formation of a transparent electrode film, and the gas introduced has basically no restriction as to its species. Specifically, Ar, He, oxygen or nitrogen can be used, and these gases may be used as mixtures thereof. When an oxide in particular is used as a material for the electrode film formation, oxygen deficiency is often brought about, so the use of oxygen is preferred.

The suitable range of surface resistance of a transparent electrode film depends on whether the electrode film is formed for the first electrode film 11 or the second electrode film 13. When the signal readout section has a CMOS structure, the surface resistance of the transparent conductive film is preferably 10,000Ω/□ or below, far preferably 1,000Ω/□ or below. On the other hand, suppose the signal readout section has a CCD structure, the surface resistance is preferably 1,000Ω/□ or below, far preferably 100Ω/□ or below. When the transparent electrode film formed is used as the second electrode film 13, the surface resistance thereof is preferably 1,000,000Ω/□ or below, far preferably 100,000Ω/□ or below.

The material which is especially suitable for a transparent electrode film is any of ITO, IZO, SnO₂, ATO (antimony-doped tin oxide), ZnO, AZO (Al-doped zinc oxide), GZO (gallium-doped zinc oxide), TiO₂ and FTO (fluorine-doped tin oxide). The light transmittance of a transparent electrode film is preferably 60% or above, far preferably 80% or above, further preferably 90% or above, still further preferably 95% or above, at the absorption peak wavelength of a photoelectric conversion film included in the photoelectric conversion section having the transparent electrode film.

When two or more intermediate layers 12 are stacked on top of each other, the first electrode film 11 and the second electrode film 13 are required to transmit light beams other than light of wavelengths detected by their respective photoelectric conversion layers, extending from the photoelectric conversion film positioned nearest the side of light incidence to the photoelectric conversion film positioned farthest from the side of light incidence. Therefore, it is appropriate that at least 90%, preferably at least 95%, of visible light, be transmitted by materials used for the first and second electrode films.

The second electrode film 13 is preferably made in a plasma-free condition. Influence of plasma exerted upon a substrate can be lessened by making the second electrode film 13 in a plasma-free condition, and thereby photoelectric conversion characteristics can be rendered favorable. The term “plasma-free” as used herein refers to the state in which no plasma develops during formation of the second electrode film 13, or plasma arriving at a substrate is reduced in quantity by adjusting the distance between a plasma source and a substrate to 2 cm or above, preferably 10 cm or above, far preferably 20 cm or above.

Examples of apparatus developing no plasma during formation of the second electrode film 13 include electron-beam evaporation apparatus (EB evaporation apparatus) and pulse-laser evaporation apparatus. As EB evaporation apparatus or pulse-laser evaporation apparatus, it is possible to use such apparatus as to be described in Yutaka Sawada (supervisor), Tomei Doden-maku no Shintenkai, CMC Publishing Co., Ltd. (1999); Yutaka Sawada (supervisor), Tomei Doden-maku no Shintenkai II, CMC Publishing Co., Ltd. (2002); Japan Society for the Promotion of Science, Tomei Doden-maku no Gijutu, Ohmsha, Ltd. (1999); and the references cited in these books. In the following descriptions, the method of forming a transparent electrode film by means of EB evaporation apparatus is referred to as “an EB evaporation method”, and the method of forming a transparent electrode film by means of pulse-laser evaporation apparatus is referred to as “a pulse-laser evaporation method”.

As to apparatus which can substantiate the condition that the distance between a plasma source and a substrate is at least 2 cm and arrival of plasma at the substrate is reduced in quantity (hereinafter referred to as “plasma-free film formation apparatus”), sputtering apparatus of opposed target type and arc plasma evaporation apparatus can be thought of. Specifically, the apparatus as described in Yutaka Sawada (supervisor), Tomei Doden-maku no Shintenkai, CMC Publishing Co., Ltd. (1999); Yutaka Sawada (supervisor), Tomei Doden-maku no Shintenkai II, CMC Publishing Co., Ltd. (2002); Japan Society for the Promotion of Science, Tomei Doden-maku no Gijutu, Ohmsha, Ltd. (1999); and the references cited in these books can be utilized.

When the transparent conductive film such as a TCO film is used as the second electrode film 13, there are cases where DC short or an increase in leak current occur. As a cause of their occurrence, it is supposed that fine cracks produced in the photoelectric conversion layer 123 are covered with a dense film such as a TCO film, causing an increase in conduction to the first electrode film 11 disposed on the opposite side. This supposition tallies with a finding that an Al electrode somewhat inferior in film quality resists causing an increase in leak current. Therefore, it is possible to significantly prevent an increase in leak current by controlling the thickness of the second electrode film 13 with reference to the thickness of the photoelectric conversion layer 123 (namely the depth of cracks). Specifically, it is advisable to adjust the thickness of the second electrode film 13 to at most one-fifth, preferably at most one-tenth, the thickness of the photoelectric conversion layer 123.

Although a steep increase in resistance is generally caused when the thickness of a conductive film is reduced beyond a certain limit, the solid-state image pickup device 1000 according to this embodiment has greater latitude in the matter of reduction range of electrode film thickness, because the sheet resistance therein is appropriately from 100 to 10,000Ω/□. In addition, the thinner the transparent conductive thin film, the smaller the quantity of light absorbed thereby, generally resulting in a rise of light transmittance. The rise of light transmittance is very favorable, because it brings about an increase in light absorption in the photoelectric conversion layer 123, causing an increase in photoelectric conversion efficiency. Considering that reduction in film thickness is attended with suppression of leak current, increase in resistance of thin film and an increase in transmittance, it is appropriate that the thickness of a transparent conductive thin film be from 5 to 100 nm, preferably from 5 to 20 nm.

Materials suitable for transparent electrode films are what can be formed into films by means of plasma-free film formation apparatus, EB evaporation apparatus or pulse-laser evaporation apparatus. For example, metals, alloys, metal oxides, metal nitrides, metal borides, organic conductive compounds and mixtures of two or more thereof can be suitably used. More specific examples of those materials include conductive metal oxides such as tin oxide, zinc oxide, indium oxide, indium zinc oxide (IZO), indium tin oxide (ITO) and indium tungsten oxide (IWO), metal nitrides such as titanium nitride, metals such as gold, platinum, silver, chromium, nickel and aluminum, mixtures or laminated composites of those metals and conductive metal oxides, inorganic conductive substances such as copper iodide and copper sulfide, organic conductive materials such as polyaniline, polythiophene and polypyrrole, and laminated composites of these conductive materials and ITO. In addition, the materials described in detail, e.g., in Yutaka Sawada (supervisor), Tomei Doden-maku no Shintenkai, CMC Publishing Co., Ltd. (1999), Yutaka Sawada (supervisor), Tomei Doden-maku no Shintenkai II, CMC Publishing Co., Ltd. (2002), and Japan Society for the Promotion of Science, Tomei Doden-maku no Gijutu, Ohmsha, Ltd. (1999), may be used.

### Fourth Embodiment

In this embodiment, the inorganic layer having the makeup shown in FIG. 12 for illustration of the third embodiment of the invention is configured not to stack two photodiodes inside the n-type silicon substrate as shown in FIG. 12 but to arrange two diodes in a direction perpendicular to the incidence direction of incident light and detect light of two different colors inside the n-type silicon substrate.

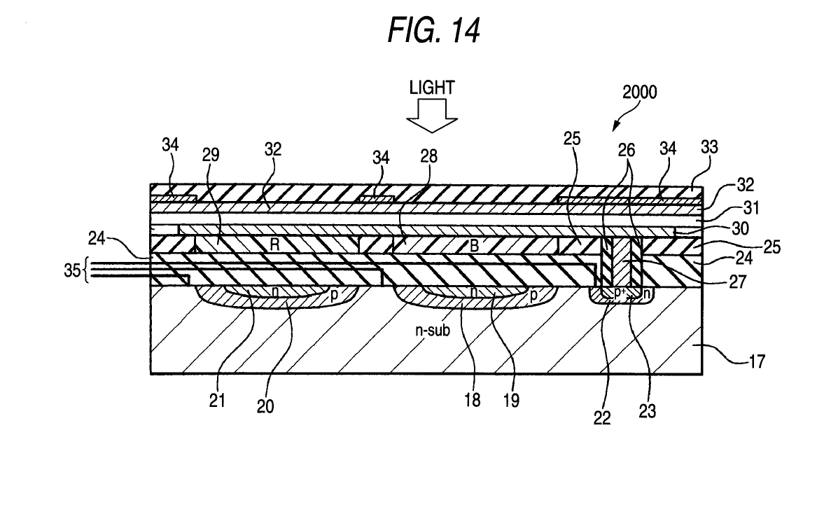

FIG. 14 is a schematic cross-sectional diagram of a pixel of solid-state image pickup device for illustrating a fourth embodiment of the invention.

A pixel of solid-state image pickup device 2000 shown in FIG. 14 is configured to include a n-type silicon substrate 17 and a photoelectric conversion section having a first electrode film 30 formed above the n-type silicon substrate 17, an intermediate layer 31 formed on the first electrode film 30 and a second electrode film 32 formed on the intermediate layer 31, and on the photoelectric conversion section a light-shielding film 34 with an aperture is further formed. By this light-shielding film 34, a limitation is imposed on the photoreceptive area of the intermediate layer 31. In addition, a transparent insulation film 33 is formed on the light-shielding film 34.

The first electrode film 30, the intermediate layer 31 and the second electrode film 32 have the same makeups as the first electrode film 11, the intermediate layer 12 and the second electrode film 13, respectively.

On the surface areas of the n-type silicon substrate 17 situated underneath the apertures of the light-shielding film 34, a photodiode having a n zone 19 and an p zone 18 and a photodiode having a n zone 21 and an p zone 20 are formed side by side. Any direction on the surface of the n-type silicon substrate 17 is perpendicular to the light incidence direction of incident light.

A color filter 28 allowing B light to pass through it is formed above the photodiode having the n zone 19 and the p zone 18 via a transparent insulation film 24, and on the color filter the first electrode film 30 is formed. Above the photodiode having the n zone 21 and the p zone 20, a color filter 29 allowing R light to pass through it is formed via the transparent insulation film 24, and on this color filter also the first electrode film 30 is formed. The environs of color filters 28 and 29 are covered with a transparent insulation film 25.

The photodiode having the n zone 19 and the p zone 18 absorbs B light having passed through the color filter 28, produces holes responsive to the light absorbed and stores the produced electrons in the p zone 18. And the photodiode having the n zone 21 and the p zone 20 absorbs R light having passed through the color filter 29, produces holes responsive to the light absorbed, and stores the produced holes in the p zone 20.

In an area shaded by the light-shielding film 34 on the surface of the p-type silicon substrate 17, an p⁺ zone 23 is formed, and the p⁺ zone 23 is surrounded by a n zone 22.

The p⁺ zone 23 is electrically connected to the first electrode film 30 via a connecting section 27 formed in an aperture piercing through the insulating films 24 and 25, so it stores the holes collected by the first electrode film 30 via the connecting section 27. The connecting section 27 is electrically insulated by an insulation film 26 from members other than the first electrode film 30 and the p⁺ zone 23.

The holes stored in the p zone 18 are converted into signals responsive to their charge quantity by means of a MOS circuit made up of p-channel MOS transistors (not illustrated in the figure) formed inside the n-type silicon substrate 17, the holes stored in the p zone 20 are converted into signals responsive to their charge quantity by means of a MOS circuit made up of p-channel MOS transistors (not illustrated in the figure) formed inside the n-type silicon substrate 17, and the holes stored in the p⁺ zone 23 are converted into signals responsive to their charge quantity by means of a MOS circuit made up of p-channel MOS transistors (not illustrated in the figure) formed inside the n zone 22. All of these signals are output to the outside of the solid-state image pickup element 2000. These MOS circuits constitute a signal readout section included in the scope of a claimed aspect of the invention. Each MOS circuit is connected to a signal readout pad not illustrated in the figure by means of wiring 35.

Alternatively, the signal readout section may be made up of CCD-amplifier combinations rather than MOS circuits. More specifically, the signal readout section may be configured so that holes stored in the p zone 18, the p zone 20 and the p⁺ zone 23 are read into CCD formed insides the n-type silicon substrate 17 and further transferred to amplifiers with the CCD, and signals responsive to the holes transferred are putout from the amplifiers.

The structure of the signal readout section, though can be a CCD or CMOS structure as mentioned above, is preferably a CMOS structure from the viewpoints of power consumption, high-speed readout, pixel addition and partial readout.

Incidentally, in FIG. 14, color separation between B light and R light is made by means of color filters 28 and 29. However, instead of disposing these color filters 28 and 29, color separation may also be made by adjusting individual depths of the pn junction face between the p zone 20 and the n zone 21 and the pn junction face between the p zone 18 and the n zone 19 to appropriate values respectively for absorption of R light and B light by their corresponding photodiodes. In this case, it is also possible to form between the n-type silicon substrate 17 and the first electrode film 30 (e.g., between the insulation film 24 and the n-type silicon substrate 17) an inorganic photoelectric conversion portion made up of inorganic materials of the kind which absorb light transmitted by the intermediate layer 31, generate charges responsive to the light absorbed and stores the charges. Herein, a MOS circuit for readout of signals responsive to the charges stored in a charge storage zone of the inorganic photoelectric conversion portion may be provided inside the n-type silicon substrate 17, and the wiring 35 may be connected to this MOS circuit also.

Alternatively, the image pickup element may also be configured so that the photodiode provided inside the n-type silicon substrate 17 is only one in number and photoelectric conversion sections are stacked in two or more layers above the n-type semiconductor substrate 17, or so that two or more photodiodes are provided inside the n-type silicon substrate 17 and photoelectric conversion sections are stacked in two or more layers above the n-type semiconductor substrate 17. On the other hand, when there's no need to produce color images, the image pickup element may be configured to have one photodiode in the n-type silicon substrate 17 and dispose one layer of photoelectric conversion section.

### Fifth Embodiment

A solid-state image pickup device according to this embodiment is not provided with the inorganic layer having the makeup shown in FIG. 12 for illustration of the third embodiment of the invention, but is configured so that a plurality of (three in here) photoelectric conversion layers are stacked on top of each other above the silicon substrate.

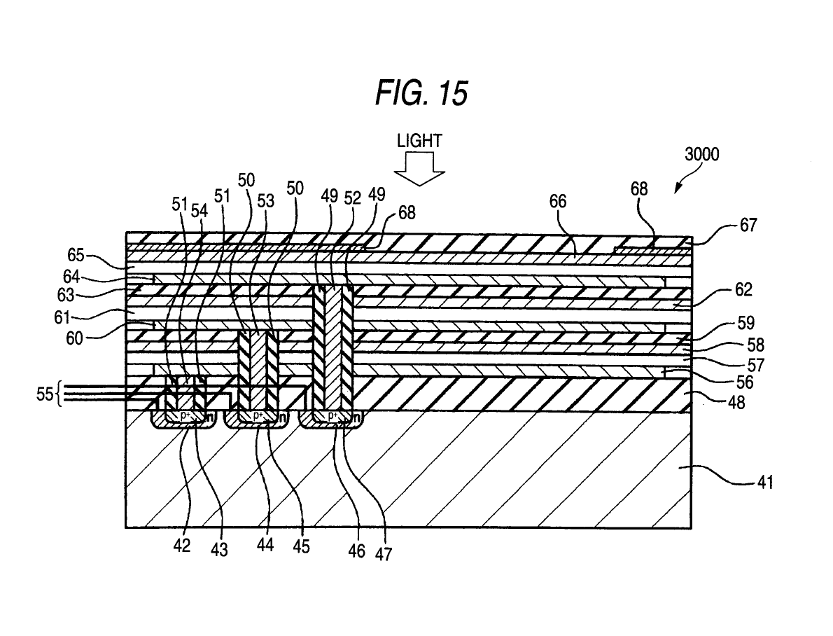

FIG. 15 is a schematic cross-sectional diagram of a pixel of solid-state image pickup device for illustrating the fifth embodiment of the invention.

The solid-state image pickup element 3000 shown in FIG. 15 is configured so that, above the silicon substrate 41, an R photoelectric conversion section including a first electrode film 56, an intermediate layer 57 formed on the first electrode film 56 and a second electrode film 58 formed on the intermediate layer 57, a B photoelectric conversion section including a first electrode film 60, an intermediate layer 61 formed on the first electrode film 60 and a second electrode film 62 formed on the intermediate layer 61, and a G photoelectric conversion section including a first electrode film 64, an intermediate layer 65 formed on the first electrode film 64 and a second electrode film 66 formed on the intermediate layer 65 are stacked in order of mention in a state of directing their respective first electrode films toward the side of the silicon substrate 41.

In addition, a transparent insulation film 48 is formed on the silicon substrate 41, and thereon is formed the R photoelectric conversion section, and on this section is formed a transparent insulation film 59, and on this film is formed the B photoelectric conversion section, and on this section is formed a transparent insulation film 63, and on this film is formed the G photoelectric conversion section, and on this section is formed a light-shielding film 68 having an aperture, and on this film is formed a transparent insulation film 67.

The first electrode film 64, the intermediate layer 65 and the second electrode film 66 which are included in the G photoelectric conversion section have the same makeups as the first electrode film 11, the intermediate layer 12 and the second electrode film 13 which are shown in FIG. 12 have respectively.

The first electrode film 60, the intermediate layer 61 and the second electrode film 62 which are included in the B photoelectric conversion section have the same makeups as the first electrode film 11, the intermediate layer 12 and the second electrode film 13 which are shown in FIG. 12 have respectively, except that a material capable of absorbing blue light and generating electrons and holes responsive to the light absorbed is used for a photoelectric conversion layer included in the intermediate layer 61.

The first electrode film 56, the intermediate layer 57 and the second electrode film 58 which are included in the R photoelectric conversion section have the same makeups as the first electrode film 11, the intermediate layer 12 and the second electrode film 13 which are shown in FIG. 12 have respectively, except that a material capable of absorbing red light and generating electrons and holes responsive to the light absorbed is used for a photoelectric conversion layer included in the intermediate layer 57.

In formation of an electron-blocking layer and a hole-blocking layer included in each of the intermediate layers 61 and 57, it is preferable that appropriate materials and compositions are selected so as not to create energy barriers to transport of signal charges in relationship between HOMO and LUMO energy levels of each photoelectric conversion layer and HOMO and LUMO energy levels of its adjacent blocking layers.

At the surface of the silicon substrate 41, p⁺ zones 43, 45 and 47 are formed in an area shaded by the light-shielding film 68, and these zones are surrounded by n zones 42, 44 and 46, respectively.

The p⁺ zone 43 is electrically connected to the first electrode film 56 via a connecting section 54 formed in an aperture piercing through an insulating film 48, and it stores the holes collected by the first electrode 56 via the connecting section 54. The connecting section 54 is electrically insulated by an insulation film 51 from members other than the first electrode film 56 and the p⁺ zone 43.

The p⁺ zone 45 is electrically connected to the first electrode film 60 via a connecting section 53 formed in an aperture piercing through an insulating film 48, the R photoelectric conversion section and an insulating film 59, and it stores the holes collected by the first electrode film 60 via the connecting section 53. The connecting section 53 is electrically insulated by an insulation film 50 from members other than the first electrode film 60 and the p⁺ zone 45.

The p⁺ zone 47 is electrically connected to the first electrode film 64 via a connecting section 52 formed in an aperture piercing through an insulating film 48, the R photoelectric conversion section, the insulating film 59, the B photoelectric conversion section and the insulating film 63, and it stores the holes collected by the first electrode film 64 via the connecting section 52. The connecting section 52 is electrically insulated by an insulation film 49 from members other than the first electrode film 64 and the p⁺ zone 47.

The holes stored in the p⁺ zone 43 are converted into signals responsive to their charge quantity by means of a MOS circuit made up of p-channel MOS transistors (not illustrated in the figure) formed inside the n zone 42, the holes stored in the p⁺ zone 45 are converted into signals responsive to their charge quantity by means of a MOS circuit made up of p-channel MOS transistors (not illustrated in the figure) formed inside the n zone 44, and the holes stored in the p⁺ zone 47 are converted into signals responsive to their charge quantity by means of a MOS circuit made up of p-channel MOS transistors (not illustrated in the figure) formed inside the n zone 46. All of these signals are output to the outside of the solid-state image pickup element 600. These MOS circuits constitute a signal readout section included in the scope of a claimed aspect of the invention. Each MOS circuit is connected to a signal readout pad not illustrated in the figure by means of wiring 55. Alternatively, the signal readout section may be made up of CCD-amplifier combinations rather than MOS circuits. More specifically, the signal readout section may be configured so that holes stored in the p⁺ zones 43, 45 and 47 are read into the CCD formed insides the silicon substrate 41 and further transferred to amplifiers with the CCD, and signals responsive to the holes transferred are putout from the amplifiers.

Additionally, it is possible to form between the silicon substrate 41 and the first electrode film 56 (e.g., between the insulation film 48 and the silicon substrate 41) an inorganic photoelectric conversion portion made up of inorganic materials which receives light transmitted by the intermediate layers 57, 61 and 65, generate charges responsive to the light absorbed and stores the charges. In this case, a MOS circuit for readout of signals responsive to the charges stored in a charge storage zone of the inorganic photoelectric conversion portion may be provided inside the silicon substrate 41, and the wiring 55 may be connected to this MOS circuit also.

As mentioned above, the structure in which the photoelectric conversion layers described in the third and forth embodiments are stacked in layers on a silicon substrate can be implemented by the makeup a shown in FIG. 15.

In the above descriptions, the photoelectric conversion layer capable of absorbing B light is intended to include photoelectric conversion layers capable of absorbing light with wavelengths ranging from 400 to 500 nm, preferably having percent absorption of 50% or above at the peak wavelength in the wavelength range specified herein. The photoelectric conversion layer capable of absorbing G light is intended to include photoelectric conversion layers capable of absorbing light with wavelengths ranging from 500 to 600 nm, preferably having percent absorption of 50% or above at the peak wavelength in the range specified herein. The photoelectric conversion layer capable of absorbing R light is intended to include photoelectric conversion layers capable of absorbing light with wavelengths ranging from 600 to 700 nm, preferably having percent absorption of 50% or above at the peak wavelength in the wavelength range specified herein.

In the makeups as described in the third and fifth embodiments according to the invention, color detection patterns are conceivable where colors are detected in the order of BGR, BRG, GBR, GRB, RBG or RGB, the upper layer first. The cases in which the top layer is G are preferable. In the case of the construction as in the forth embodiment, on the other hand, it is possible to make a combination of the R layer as the upper layer with the B and G layers juxtaposed in one plane, a combination of the B layer as the upper layer with the G and R layers juxtaposed in one plane, or a combination of the G layer as the upper layer with the B and R layers juxtaposed in one plane. Of these combinations, the combination of the G layer as the upper layer with the B and R layers juxtaposed in one plane, such as the makeup shown in FIG. 13, is preferred over the others.

### Sixth Embodiment

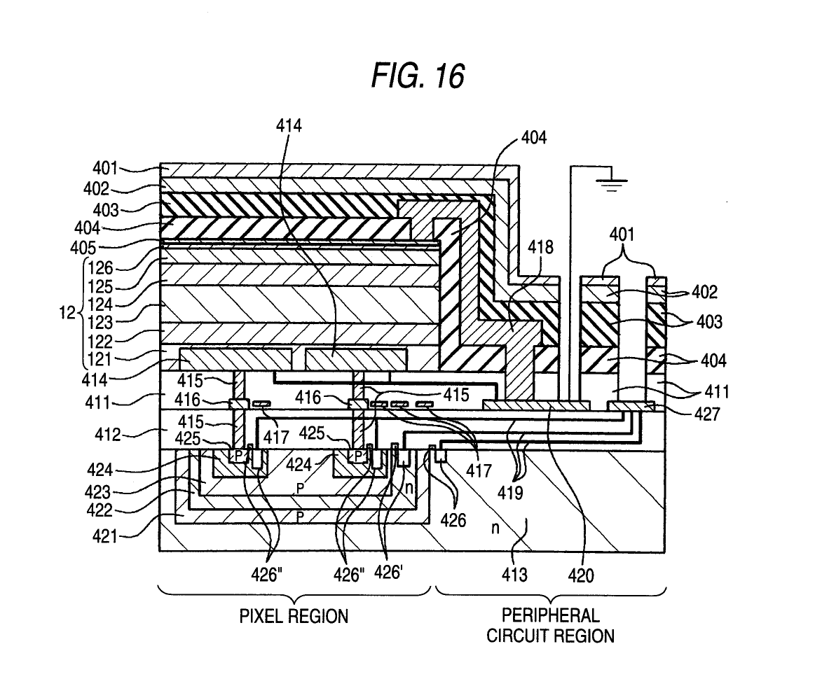

FIG. 16 is a schematic cross-sectional diagram of a solid-state image pickup device for illustrating a sixth embodiment of the invention. In FIG. 16, cross-sections of two pixels in a pixel region which detects light and stores charges and a cross-section of a peripheral circuit region wherein wiring for connection to electrodes in the pixel region and bonding PADs for connection to the wiring are formed are drawn together.

In the pixel region, a p zone 421 is formed at a surface area of the n-type silicon substrate 413. On the surface area of the p zone 421, an n zone 422 is formed, and on the surface area of the n zone 422 is formed a p zone 423. And at surface areas of the p zone 423 are formed n zones 424 respectively.

The p zone 421 stores holes of a red (R) component converted photoelectrically by a pn junction with the n-type silicon substrate 413. A change in potential of the p zone 421 by storage of holes of the R component is read out of a MOS transistor 426 formed in the n-type silicon substrate into a signal readout PAD 427 via metal wiring 419 connected to the MOS transistor.

The p zone 423 stores holes of a blue (B) component converted photoelectrically by a pn junction with the n zone 422. A change in potential of the p zone 423 by storage of holes of the B component is read out of a MOS transistor 426′ formed in the n zone 422 into a signal readout PAD 427 via metal wiring 419 connected to the MOS transistor.

In each n zone 424 is formed a hole storage zone 425 including a p zone storing holes of a green (G) component generated in the photoelectric conversion layer 123 stacked above the n-type silicon substrate 413. A change in potential of the hole storage zone 425 by storage of holes of the G component is read out of a MOS transistor 426″ formed in the n zone 424 into a signal readout PAD 427 via metal wiring 419 connected to the MOS transistor. In general, the signal readout PAD 427 is provided independently for each of the transistors by which different color components are readout respectively.

Herein, the p zones, the n zones, the transistors and the metal wiring are shown schematically. However, their respective structures should not be construed as being limited to those shown herein, but optimum ones may be chosen as appropriate. Since the separation between B light and R light is made by depth in the silicon substrate, the depth of each pn junction below the surface of the silicon substrate and the dope concentrations of various impurities are of importance. Techniques used in general CMOS image sensors can be applied to CMOS circuits making the readout section. Specifically, the techniques, from low-noise readout columns and CDS circuits to circuit makeup for reducing the number of transistors in the pixel region can be applied.

On the n-type silicon substrate 413 is formed a transparent insulating film 412 whose main ingredient is silicon oxide or silicon nitride, and on the insulating film 412 are formed transparent insulating films 411 whose main ingredient is silicon oxide or silicon nitride. As to the thickness of the insulating film 412, the thinner the better. And the suitable thickness is 5 μm or below, preferably 3 μm or below, far preferably 2 μm or below, further preferably 1 μm or below.

In each of insulating films 411 and 412, plugs 415 predominantly composed of, e.g., tungsten, by which the first electrode film 414 is electrically connected to the p zones 425 as hole storage zones, are formed, and each pair of plugs 415 are connected with a pad 416 as a joint placed between the insulating film 411 and the insulating film 412. As the pad 416, a pad that is predominantly composed of aluminum is suitably used. In the insulating film 412, the metal wiring 419 and gate electrodes for the transistors 426, 426′ and 426″ are also formed. Herein, it is preferable that barrier layers including the metal wiring are provided. The plugs 415 as a pair are provided for every one pixel.

In the insulating film 411, a light-shielding film 417 is provided for prevention of noises traceable to charges developing at each pn junction between n zone 424 and p zone 425. As the light-shielding film 417, a film that is predominantly composed of tungsten or aluminum is used. In the insulating film 411, a bonding PAD 420 (PAD for supplying power from the outside) and a signal readout PAD 427 are further formed, and besides, metal wiring to connect the bonding PAD 420 to the first electrode film 414 is formed.

On the plug 415 provided in the insulating film 411 for each of the pixels, the transparent first electrode film 414 is formed. The first electrode film 414 is divided between pixels, and the size of such a film allocated to each pixel determines the light-receiving area. To the first electrode film 414, a bias is given via the wiring from the bonding PAD 420. Herein, it is preferable to configure so that holes can be stored in the hole storage zones 425 by giving the first electrode 414 a bias negative for a second electrode film 405 described hereinafter.

On the first electrode film 414, an intermediate layer having the same makeup as in FIG. 12 is formed, and thereon the second electrode film 405 is formed.

On the second electrode film 405 is formed a protective film 404 that is predominantly composed of, e.g., silicon nitride and has a function of protecting the intermediate layer 12. In the protective film 404, an aperture is formed at a position deviating from the area lying right above the first electrode film 414 in the pixel region. In each of the insulating film 411 and the protective film 404, an aperture is further formed at a position right on a part of the bonding PAD 420. And the wiring 418 made of, e.g., aluminum for electrically connecting between the second electrode film 405 and the bonding PAD 420 via the parts made bare by those two apertures and giving a potential to the second electrode film 405 is formed inside the apertures and on the protective film 404. As a material of the wiring 418, an aluminum-containing alloy, such as an Al—Si or Al—Cu alloy, can also be used.

On the wiring 418, a protective film 403 whose main ingredient is, e.g., silicon nitride is formed in order to protect the wiring 418, and on the protective film 403 is formed an infrared cutoff dielectric multilayer film 402, and further thereon is formed an antireflective film 401.

The first electrode film 414 performs the same function as the first electrode film 11 shown in FIG. 12. The second electrode film 405 performs the same function as the second electrode film 13 shown in FIG. 12.

The makeup mentioned above enables detection of three colors BGR by one pixel and pickup of color images. In the makeup shown in FIG. 16, R and B are each used as a value common to the two pixels, but G values of the two pixels are used individually. However, color images of good quality can be produced even by such a makeup since the sensitivity of G is important in producing color images.

The solid-state image pickup devices illustrated above can be applied to image pickup devices including digital cameras, video cameras, facsimiles, scanners and copiers. In addition, they can also be utilized as light sensors, such as biosensors and chemical sensors.

Examples of materials for the insulating films seen in descriptions of the foregoing embodiments include SiOx, SiNx, BSG, PSG, BPSG, metal oxides such as Al₂O₃, MgO, GeO, NiO, CaO, BaO, Fe₂O₃, Y₂O₃ and TiO₂, and metal fluorides such as MgF₂, LiF, AlF₃ and CaF₂. Of these materials, SiOx, SiNx, BSG, PSG and BPSG are preferred over the others.

Additionally, it doesn't matter whether holes or electrons are used in reading signals out of members other than photoelectric conversion layers in the third to sixth embodiments. More specifically, as mentioned above, the image pickup device may be so configured that holes are stored in not only an inorganic photoelectric conversion section provided between a semiconductor substrate and a photoelectric conversion section stacked on the semiconductor substrate but also photodiodes formed insides the semiconductor substrate, and signals responsive to these holes are read by a signal readout section, or may be so configured that electrons are stored in an inorganic photoelectric conversion section and photodiodes formed inside the semiconductor substrate, and signals responsive to these electrons are read by a signal readout section.

In each of the third to sixth embodiments, though the makeup shown in FIG. 13 is adopted as the photoelectric conversion section provide above the silicon substrate, any of the makeups shown in FIG. 1 and FIGS. 6 to 9 can be adopted as well. According to the makeup shown in FIG. 13, blocking of both electrons and holes can be achieved, so dark current suppression effect can be enhanced. On the other hand, it becomes feasible to make the electrode opposed to the electrode on the side of light incidence act as an electrode for extraction of electrons merely by modifying the makeup shown in FIG. 2 so as to connect the connecting section 9 to the second electrode 13, or the makeup shown in FIG. 14 so as to connect the connecting section 27 to the second electrode 13, or the makeup shown in FIG. 15 so as to connect the connecting section 54 to the second electrode 58, the connecting section 53 to the second electrode 62 and the connecting section 52 to the second electrode 66.

Each of the solid-state image pickup devices illustrated in accordance with embodiments of the invention has a makeup that a large number of pixels each of which is shown in any of FIG. 12 to FIG. 16 are arranged in array on one plane, and each pixel can provide RGB color signals. Therefore, this one pixel can be regarded as a photoelectric conversion element to convert light of RGB into electric signals, and the solid-state image pickup devices described as embodiments of the invention can be said that it has the makeup in which a large number of photoelectric conversion elements as shown in any of FIG. 12 to FIG. 16 are arranged in array on one plane.

### EXAMPLES

In the following examples, it is demonstrated that the charge blocking layers of multiple-layer structure according to the invention have higher dark-current suppression effect than traditional charge blocking layers of single-layer structure.

The Ea and Ip values of a hole blocking layer or an electron blocking layer are measured in the following manners, respectively, and optimum materials are chosen in each Example.

Ionization potential (Ip) measurements are carried out with a surface analyzer Model AC-1 made by Riken Keiki Co., Ltd. More specifically, an organic material to be examined is formed into a layer with a thickness of about 100 nm on a quartz substrate, and an Ip measurement thereof is made under a condition that the quantity of light is from 20 to 50 nW and the analysis area is 4 mmφ. Ip measurements in the cases of compounds having great ionization potentials are made by UPS (Ultraviolet Photoelectron Spectroscopy).

In order to determine electron affinity, the specular of a material formed into a layer is measured first, and then the energy of its absorption edge is determined. The value of electron affinity is calculated by subtracting the energy of this absorption edge from the ionization potential value of the material.

### Example 1

A glass substrate with an ITO electrode 25 mm square was subjected to successive 15 minutes' ultrasonic cleaning treatments with acetone, Semicoclean and isopropyl alcohol (IPA), respectively. After boiling IPA cleaning in conclusion, UV/O₃ cleaning was further carried out. The thus cleaned substrate was transferred to a organic evaporation room, and the room pressure was reduced to 1×10⁻⁴ Pa or below. Thereafter, while rotating a substrate holder, quinacridone (a product of DOJINDO) at least triple purified by sublimation was evaporated onto the ITO electrode so as to have a thickness of 1,000 Å at an evaporation speed of 0.5 to 1 Å/sec in accordance with a resistance heating method, thereby forming a photoelectric conversion layer. In succession thereto, the compound HB-1 purified by sublimation was evaporated so as to have a thickness of 150 Å at an evaporation speed of 1 to 2 Å/sec, thereby forming the first layer of a hole blocking layer. Thereafter, the compound HB-2 purified by sublimation was evaporated so as to have a thickness of 150 Å at an evaporation speed of 1 to 2 Å/sec, thereby forming the second layer of a hole blocking layer.

Next, the thus treated substrate was transported into a metal evaporation room while maintaining a vacuum. Thereafter, as the room was maintained at 1×10⁻⁴ Pa of vacuum, Al was evaporated onto the second layer of the hole blocking layer so as to have a thickness of 800 Å, thereby forming an opposite electrode. Herein, the area of the photoelectric conversion zone formed by Al as an electrode opposed to the ITO electrode was adjusted to 2 mm×2 mm. While avoiding contact with the air, this substrate was transported into a globe box in which both moisture and oxygen were held at 1 ppm or below, and sealed in an absorbent-covered stainless sealing can by use of a UV cure resin.

By means of a constant-energy quantum efficiency measuring device made by Optel (wherein Keithley 6430 was used as a source meter), the element thus prepared was examined for a value of dark current flowing under no irradiation with light and a value of photocurrent flowing under irradiation with light when an external electric field of 1.0×10⁶ V/cm was applied thereto, and further for an external quantum efficiency (IPCE) at a wavelength 550 nm derived from those values. As to the IPCE, the quantum efficiency was calculated using the signal current value obtained by subtracting the dark current value from the photocurrent value. The quantity of light irradiated was adjusted to 50 μW/cm².

### Example 2

Onto the ITO electrode-equipped glass substrate cleaned in the same manner as in Example 1, the compound EB-1 purified by sublimation was evaporated first under the same conditions as in Example 1 so as to have a thickness of 150 Å at an evaporation speed of 1 to 2 Å/sec, thereby forming the first layer of an electron blocking layer. In succession thereto, the compound EB-2 purified by sublimation was evaporated so as to have a thickness of 150 Å at an evaporation speed of 1 to 2 Å/sec, thereby forming the second layer of an electron blocking layer. Subsequently thereto, quinacridone (a product of DOJINDO) at least triple purified by sublimation was evaporated so as to have a thickness of 1,000 Å at an evaporation speed of 0.5 to 1 Å/sec, thereby forming a photoelectric conversion layer. Next, as in the case of Example 1, the thus prepared substrate was transported into a metal evaporation room, subjected to Al deposition, and further sealed. Photocurrent, dark current and IPCE measurements of the thus prepared element were carried out.

### Example 3

An electron blocking layer of double-layer structure was formed by evaporating EB-1 and EB-2 sequentially onto the cleaned substrate with an ITO electrode in the same manner as in Example 2. In succession thereto, quinacridone (a product of DOJINDO) at least triple purified by sublimation was evaporated so as to have a thickness of 1,000 Å at an evaporation speed of 0.5 to 1 Å/sec, thereby forming a photoelectric conversion layer. Thereafter, HB-1 and HB-2 were evaporated sequentially so as to have their individual thickness of 150 Å at an evaporation speed of 1 to 2 Å/sec, thereby forming a hole blocking layer of double-layer structure. Next, as in the case of Example 1, the thus prepared substrate was transported into a metal evaporation room, subjected to Al deposition, and further sealed. Photocurrent, dark current and IPCE measurements of the thus prepared element were carried out.

### Example 4

Onto the ITO electrode-equipped glass substrate cleaned in the same manner as in Example 1, quinacridone (a product of DOJINDO) at least triple purified by sublimation was evaporated so as to have a thickness of 1,000 Å at an evaporation speed of 0.5 to 1 Å/sec in accordance with a resistance heating method under the same conditions as in Example 1, thereby forming a photoelectric conversion layer. In succession thereto, the compound HB-1 purified by sublimation was evaporated so as to have a thickness of 100 Å at an evaporation speed of 1 to 2 Å/sec, thereby forming the first layer of a hole blocking layer. Subsequently thereto, the compound HB-2 purified by sublimation was evaporated so as to have a thickness of 100 Å at an evaporation speed of 1 to 2 Å/sec, thereby forming the second layer of a hole blocking layer. Thereafter, the compound HB-5 purified by sublimation was evaporated so as to have a thickness of 100 Å at an evaporation speed of 1 to 2 Å/sec, thereby forming the third layer of a hole blocking layer. Next, as in the case of Example 1, the thus prepared substrate was transported into a metal evaporation room, subjected to Al deposition, and further sealed. Then, photocurrent, dark current and IPCE measurements of the thus prepared element were carried out.

### Example 5

Onto the ITO-equipped substrate cleaned in the same manner as in Example 1, the compound EB-1 purified by sublimation was evaporated so as to have a thickness of 100 Å at an evaporation speed of 1 to 2 Å/sec under the same conditions as in Example 1, thereby forming the first layer of an electron blocking layer. Subsequently thereto, the compound EB-2 purified by sublimation was evaporated so as to have a thickness of 100 Å at an evaporation speed of 1 to 2 Å/sec, thereby forming the second layer of an electron blocking layer. In succession thereto, m-MTDATA purified by sublimation was evaporated so as to have a thickness of 100 Å at an evaporation speed of 1 to 2 Å/sec, thereby forming the third layer of an electron blocking layer. Thereafter, quinacridone (a product of DOJINDO) at least triple purified by sublimation was evaporated so as to have a thickness of 1,000 Å at an evaporation speed of 0.5 to 1 Å/sec, thereby forming a photoelectric conversion layer. Next, as in the case of Example 1, the thus prepared substrate was transported into a metal evaporation room, subjected to Al deposition, and further sealed. Then, photocurrent, dark current and IPCE measurements of the thus prepared element were carried out.

### Example 6

As in the case of Example 5, EB-1, EB-2 and m-MTDATA were sequentially evaporated onto the cleaned ITO-equipped substrate, thereby forming an electron blocking layer of triple-layer structure. In succession thereto, quinacridone (a product of DOJINDO) at least triple purified by sublimation was evaporated so as to have a thickness of 1,000 Å at an evaporation speed of 0.5 to 1 Å/sec, thereby forming a photoelectric conversion layer. Thereafter, HB-1, HB-2 and HB-5 were evaporated sequentially so as to have their individual thickness of 100 Å at an evaporation speed of 1 to 2 Å/sec, thereby forming a hole blocking layer of triple-layer structure. Next, as in the case of Example 1, the thus prepared substrate was transported into a metal evaporation room, subjected to Al deposition, and further sealed. Then, photocurrent, dark current and IPCE measurements of the thus prepared element were carried out.

### Example 7

Onto the ITO electrode-equipped substrate cleaned in the same manner as in Example 1, the compound EB-3 was evaporated so as to have a thickness of 1,000 Å at an evaporation speed of 0.5 to 1 Å/sec, and subsequently thereto quinacridone (a product of DOJINDO) at least triple purified by sublimation was evaporated so as to have a thickness of 1,000 Å at an evaporation speed of 0.5 to 1 Å/sec, thereby forming a photoelectric conversion layer. In succession thereto, Alq3 was evaporated so as to have a thickness of 500 Å at an evaporation speed of 0.5 to 1.0 Å/sec. Then, this substrate was transported into a metal evaporation room as it is kept in a vacuum state. Thereafter, while maintaining the degree of vacuum in the room at 1×10⁻⁴ Pa or below, SiO was evaporated so as to have a thickness of 200 Å at an evaporation speed of 0.7 to 0.9 Å/sec in accordance with a heating evaporation method, thereby forming a hole-blocking layer of double-layer structure. In the next place, while maintaining the degree of vacuum, the resulting substrate was transported into a sputter room, and ITO was formed into a 5 nm-thick film by RF sputtering, thereby providing an upper electrode. As in the case of Example 1, after sealing the thus made photoelectric conversion element, photocurrent, dark current and IPCE measurements were made on this element.

### Comparative Example 1

Onto the ITO electrode-equipped glass substrate cleaned in the same manner as in Example 1, quinacridone (a product of DOJINDO) at least triple purified by sublimation was evaporated so as to have a thickness of 1,000 Å at an evaporation speed of 0.5 to 1 Å/sec in accordance with a resistance heating method under the same conditions as in Example 1, thereby forming a photoelectric conversion layer. In succession thereto, the compound HB-1 purified by sublimation was evaporated so as to have a thickness of 300 Å at an evaporation speed of 1 to 2 Å/sec, thereby forming a hole blocking layer of single-layer structure. Next, as in the case of Example 1, the thus prepared substrate was transported into a metal evaporation room, subjected to Al deposition, and further sealed. Then, photocurrent, dark current and IPCE measurements of the thus prepared element were carried out.

### Comparative Example 2

Onto the ITO electrode-equipped glass substrate cleaned in the same manner as in Example 1, quinacridone (a product of DOJINDO) at least triple purified by sublimation was evaporated so as to have a thickness of 1,000 Å at an evaporation speed of 0.5 to 1 Å/sec in accordance with a resistance heating method under the same conditions as in Example 1, thereby forming a photoelectric conversion layer. In succession thereto, the compound HB-2 purified by sublimation was evaporated so as to have a thickness of 300 Å at an evaporation speed of 1 to 2 Å/sec, thereby forming a hole blocking layer of single-layer structure. Next, as in the case of Example 1, the thus prepared substrate was transported into a metal evaporation room, subjected to Al deposition, and further sealed. Then, photocurrent, dark current and IPCE measurements of the thus prepared element were carried out.

### Comparative Example 3

Onto the ITO electrode-equipped glass substrate cleaned in the same manner as in Example 1, quinacridone (a product of DOJINDO) at least triple purified by sublimation was evaporated so as to have a thickness of 1,000 Å at an evaporation speed of 0.5 to 1 Å/sec in accordance with a resistance heating method under the same conditions as in Example 1, thereby forming a photoelectric conversion layer. In succession thereto, the compound HB-5 purified by sublimation was evaporated so as to have a thickness of 300 Å at an evaporation speed of 1 to 2 Å/sec, thereby forming a hole blocking layer of single-layer structure. Next, as in the case of Example 1, the thus prepared substrate was transported into a metal evaporation room, subjected to Al deposition, and further sealed. Then, photocurrent, dark current and IPCE measurements of the thus prepared element were carried out.

### Comparative Example 4

Onto the ITO-equipped substrate cleaned in the same manner as in Example 1, the compound EB-1 purified by sublimation was evaporated so as to have a thickness of 300 Å at an evaporation speed of 1 to 2 Å/sec under the same conditions as in Example 1, thereby forming an electron blocking layer of single-layer structure. In succession thereto, quinacridone (a product of DOJINDO) at least triple purified by sublimation was evaporated so as to have a thickness of 1,000 Å at an evaporation speed of 0.5 to 1 Å/sec, thereby forming a photoelectric conversion layer. Next, as in the case of Example 1, the thus prepared substrate was transported into a metal evaporation room, subjected to Al deposition, and further sealed. Then, photocurrent, dark current and IPCE measurements of the thus prepared element were carried out.

### Comparative Example 5

Onto the ITO-equipped substrate cleaned in the same manner as in Example 1, the compound EB-2 purified by sublimation was evaporated so as to have a thickness of 300 Å at an evaporation speed of 1 to 2 Å/sec under the same conditions as in Example 1, thereby forming an electron blocking layer of single-layer structure. In succession thereto, quinacridone (a product of DOJINDO) at least triple purified by sublimation was evaporated so as to have a thickness of 1,000 Å at an evaporation speed of 0.5 to 1 Å/sec, thereby forming a photoelectric conversion layer. Next, as in the case of Example 1, the thus prepared substrate was transported into a metal evaporation room, subjected to Al deposition, and further sealed. Then, photocurrent, dark current and IPCE measurements of the thus prepared element were carried out.

### Comparative Example 6

Onto the ITO-equipped substrate cleaned in the same manner as in Example 1, m-MTDATA purified by sublimation was evaporated so as to have a thickness of 300 Å at an evaporation speed of 1 to 2 Å/sec under the same conditions as in Example 1, thereby forming an electron blocking layer of single-layer structure. In succession thereto, quinacridone (a product of DOJINDO) at least triple purified by sublimation was evaporated so as to have a thickness of 1,000 Å at an evaporation speed of 0.5 to 1 Å/sec, thereby forming a photoelectric conversion layer. Next, as in the case of Example 1, the thus prepared substrate was transported into a metal evaporation room, subjected to Al deposition, and further sealed. Then, photocurrent, dark current and IPCE measurements of the thus prepared element were carried out.

### Comparative Example 7

As in Example 7, onto the cleaned ITO electrode-equipped substrate was evaporated the compound HB-3 so as to have a thickness of 1,000 Å at an evaporation speed of 0.5 to 1 Å/sec, and subsequently, was evaporated quinacridone (a product of DOJINDO) at least triple purified by sublimation so as to have a thickness of 1,000 Å at an evaporation speed of 0.5 to 1 Å/sec, thereby forming a photoelectric conversion layer. In succession thereto, Alq3 was evaporated so as to have a thickness of 500 Å at an evaporation speed of 0.5 to 1.0 Å/sec. In the next place, while keeping it in a vacuum state, the resulting substrate was transported into a sputter room, and thereon ITO was formed into a 5 nm-thick film by RF sputtering, thereby providing an upper electrode. As in the case of Example 1, after sealing the thus made photoelectric conversion element, photocurrent, dark current and IPCE measurements were made on this element.

### Comparative Example 8

Onto the ITO electrode-equipped substrate cleaned in the same manner as in Example 1, the compound HB-3 was evaporated so as to have a thickness of 1,000 Å at an evaporation speed of 0.5 to 1 Å/sec, and subsequently thereto quinacridone (a product of DOJINDO) at least triple purified by sublimation was evaporated so as to have a thickness of 1,000 Å at an evaporation speed of 0.5 to 1 Å/sec, thereby forming a photoelectric conversion layer. In succession thereto, this substrate was transported into a metal evaporation room as it is kept in a vacuum state. Thereafter, while maintaining the degree of vacuum in the room at 1×10⁻⁴ Pa or below, SiO was evaporated so as to have a thickness of 200 Å at an evaporation speed of 0.7 to 0.9 Å/sec in accordance with a heating evaporation method, and further the resulting substrate was transported into a sputter room while maintaining the degree of vacuum, and thereon ITO was formed into a 5 nm-thick film by RF sputtering. Thus, an upper electrode was provided. As in the case of Example 1, after sealing the thus made photoelectric conversion element, photocurrent, dark current and IPCE measurements were made on this element.

### (Results)

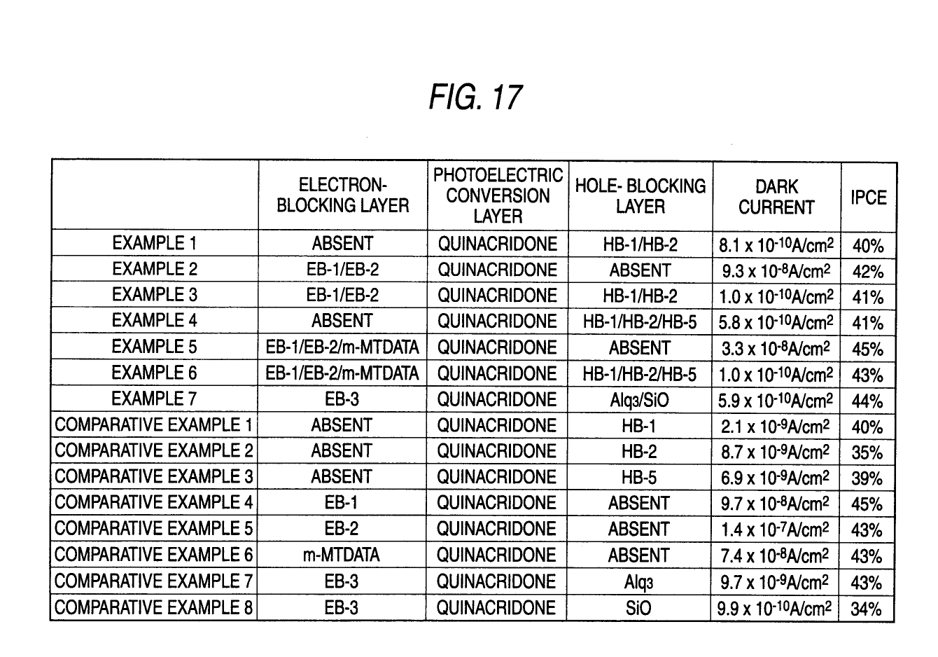

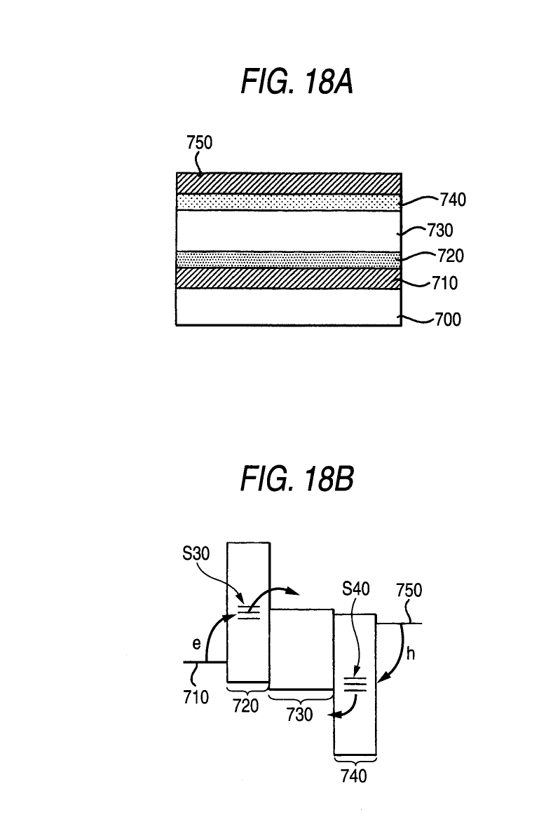

Measurement results in Examples 1 to 6 and Comparative Examples 1 to 6 are shown in FIG. 17.

With respect to the placement of a hole blocking layer, the comparison of Example 1 with Comparative Examples 1 and 2 reveals that, as shown in FIG. 17, Example 1 where the hole blocking layer is formed of two layers delivers a greater reduction in dark current than either of Comparative Examples 1 and 2 where the hole blocking layer is a single layer. In addition, when Example 4 is compared with Comparative Examples 1, 2 and 3, as shown in FIG. 17, Example 4 where the hole blocking layer is formed of three layers delivers a greater reduction in dark current than any of Comparative Examples 1, 2 and 3.

With respect to the placement of an electron blocking layer, the comparison of Example 2 with Comparative Examples 4 and 5 reveals that, as shown in FIG. 17, Example 2 where the electron blocking layer is formed of two layers delivers a greater reduction in dark current than either of Comparative Examples 4 and 5 where the electron blocking layer is a single layer. In addition, when Example 5 is compared with Comparative Examples 4, 5 and 6, as shown in FIG. 15, Example 5 where the electron blocking layer is formed of three layers delivers a greater reduction in dark current than any of Comparative Examples 4, 5 and 6.

In Examples 3 and 6 where the hole blocking layer and the electron blocking layer are each configured so as to have a multiple-layer structure, it is successful to reduce dark current to a minimum without lowering the photoelectric conversion efficiency.

Furthermore, it has been shown that dark current was smaller and higher efficiency was achieved in Example 7 where the hole-blocking layer had a multilayer structure made up of an inorganic material layer and an organic material layer than in Comparative Examples 7 and 8 where the hole-blocking layers were a single inorganic material layer and a single organic material layer, respectively.

In accordance with the invention, as described above, injection of carriers from electrodes via intermediate levels under application of an external electric field can be inhibited with efficiency by charge blocking layers being configured to have multiple-layer structures even when the total thickness thereof is a small value. Therefore, it becomes feasible to significantly enhance the photocurrent/dark current ratio of a photoelectric conversion element. In addition, reduction in drive voltage (voltage applied to electrodes) can also be attained by reduction in total thickness of charge blocking layers.

In accordance with the invention, it is feasible to provide a photoelectric conversion element that can effectively reduce dark current by suppressing the injection of charges (electrons and holes) from electrodes into its photoelectric conversion layer.

The entire disclosure of each and every foreign patent application from which the benefit of foreign priority has been claimed in the present application is incorporated herein by reference, as if fully set forth.

1-23. (canceled)

24. A method for forming an image comprising:
providing a photoelectric conversion element comprising a photoelectric conversion section that includes:
a pair of electrodes;
a photoelectric conversion layer disposed between the pair of electrodes; and
a first charge-blocking layer which is disposed between one of the pair of electrodes and the photoelectric conversion layer and comprises a plurality of layers;
applying a voltage to the pair of electrodes so that the first charge-blocking layer restrains injection of charges from the one of the electrodes into the photoelectric conversion layer such that a value obtained by dividing the voltage applied to the pair of electrodes by an electrode-to-electrode distance of the pair of electrodes is from 1.0×10⁵ V/cm to 1.0×10⁷ V/cm.

25. The method for forming the image according to claim 24,
wherein the photoelectric conversion element further comprises:
a semiconductor substrate above which the photoelectric conversion section is disposed in at least one layer;
a charge storage section, formed in the semiconductor substrate, that stores charges generated in the photoelectric conversion layer of the photoelectric conversion section; and
a connecting section that connects electrically an electrode for extracting the charges, which is one of the pair of electrodes in the photoelectric conversion section, to the charge storage section.

26. The method for forming the image according to claim 25, wherein at least two of the plurality of layers included in the first charge-blocking layer are different from each other in materials with which they are made.

27. The method for forming the image according to claim 25, wherein the first blocking layer has a thickness of 10 nm to 200 nm.

28. The method for forming the image according to claim 25, wherein the first charge-blocking layer comprises at least one inorganic material layer including an inorganic material.

29. The method for forming the image according to claim 28, wherein the first charge-blocking layer further comprises at least one organic material layer including an organic material.

30. The method for forming the image according to claim 25, wherein the first charge-blocking layer comprises an inorganic material layer including an inorganic material and an organic material layer including an organic material, in order of mention when viewed from a side of the one of the electrodes.

31. The method for forming the image according to claim 25,
wherein the photoelectric conversion section further comprises between the other one of the pair of electrodes and the photoelectric conversion layer a second charge-blocking layer that restrains injection of charges from the other one of the electrodes into the photoelectric conversion layer when a voltage is applied to the pair of electrodes, and
wherein the second charge-blocking layer comprises a plurality of layers.

32. The method for forming the image according to claim 31, wherein at least two of the plurality of layers included in the second charge-blocking layer are different from each other in materials with which they are made.

33. The method for forming the image according to claim 31, wherein the second blocking layer has a thickness of 10 nm to 200 nm.

34. The method for forming the image according to claim 31, wherein the second charge-blocking layer comprises an inorganic material layer including at least one inorganic material.

35. The method for forming the image according to claim 34, wherein the second charge-blocking layer further comprises an organic material layer including an organic material.

36. The method for forming the image according to claim 31, wherein the second charge-blocking layer comprises an inorganic material layer including an inorganic material and an organic material layer including an organic material, in order of mention when viewed from the side of the other one of the electrodes.

37. The method for forming the image according to claim 28, wherein the inorganic material comprises Si, Mo, Ce, Li, Hf, Ta, Al, Ti, Zn, W, or Zr.

38. The method for forming the image according to claim 28, wherein the inorganic material comprises an oxide.

39. The method for forming the image according to claim 38, wherein the oxide comprises SiO.

40. The method for forming the image according to claim 25, wherein each of the one pair of electrodes comprises a transparent conductive oxide (TCO).

41. The method for forming the image according to claim 25, wherein wherein the photoelectric conversion element further comprises, in the semiconductor substrate, an in-substrate photoelectric conversion portion that absorbs light transmitted by the photoelectric conversion layer of the photoelectric conversion section, generates charges responsive to the transmitted light and stores the charges.

42. The method for forming the image according to claim 41, wherein the in-substrate photoelectric conversion portion comprises a plurality of photodiodes which are stacked in the semiconductor substrate and absorb light of different colors, respectively.

43. The method for forming the image according to claim 41, wherein the in-substrate photoelectric conversion portion comprises a plurality of photodiodes juxtaposed in a direction perpendicular to an incidence direction of incident light in the semiconductor substrate, the photodiodes absorbing light of different colors respectively.

44. The method for forming the image according to claim 42,
wherein the photoelectric conversion section is disposed in one layer above the semiconductor substrate,
wherein the plurality of photodiodes are a photodiode for blue color, which has a pn junction face formed at a position allowing absorption of blue light, and a photodiode for red color, which has a pn junction face formed at a position allowing absorption of red light, and
wherein the photoelectric conversion layer of the photoelectric conversion section is a layer capable of absorbing green light.

45. The method for forming the image according to claim 25, wherein the providing the photoelectric conversion element step comprises providing a solid-state image pickup device comprising:
the photoelectric conversion element and at least another photoelectric conversion element in an array arrangement; and
a signal readout section that reads out signals responsive to the charges stored in each of the charge storage sections of said plurality of photoelectric conversion elements.
